(19) United States
(12) Patent Application Publication
(10) Pub. No.: US 2022/0293712 A1
(43) Pub. Date: Sep. 15, 2022

(54) DISPLAY DEVICE

(71) Applicant: Samsung Display Co., LTD., Yongin-si, Gyeonggi-do (KR)

(72) Inventors: Jun Hyun PARK, Suwon-si (KR); Dong Woo KIM, Yongin-si (KR); Sung Jae MOON, Seongnam-si (KR); Kang Moon JO, Hwaseong-si (KR)

(21) Appl. No.: 17/635,292

(22) PCT Filed: Nov. 26, 2019
(86) PCT No.: PCT/KR2019/016395

§ 371 Date: Feb. 14, 2022

(30) Foreign Application Priority Data
Aug. 20, 2019 (KR) 10-2019-0101621

(51) Int. Cl. H01L 27/32

(52) U.S. Cl. CPC H01L 27/3276; H01L 27/3218

(57) ABSTRACT

A display device has a display area and a non-display area extending around the display area and includes: a plurality of pixels in the display area, a first voltage line in the display area; and a second voltage line in the non-display area. Each of the pixels includes an electrode pattern connected to the first voltage line, a pixel-defining film on the electrode pattern, an emission layer on the pixel-defining film, and a common electrode on the emission layer. The pixels include first-type pixels in which the common electrode and the electrode pattern are connected through an opening hole formed in the pixel-defining film and exposing part of the electrode pattern and second-type pixels in which the opening hole is not formed and the common electrode and the electrode pattern are not connected. The first-type pixels and the second-type pixels are adjacent to each other.

### CROSS-REFERENCE TO RELATED APPLICATION

This application is a U.S. National Phase Patent Application of International Patent Application Number PCT/KR2019/016395, filed on Nov. 26, 2019, which claims priority to Korean Patent Application Number 10-2019-0101621, filed on Aug. 20, 2019, the entire content of all of which is incorporated herein by reference.

### BACKGROUND

### 1. Field

Aspects of embodiments of the disclosure relate to a display device.

### 2. Description of the Related Art

An electronic device for providing an image to a user, such as a television (TV), a smartphone, a tablet personal computer (PC), a digital camera, a notebook computer, or a navigation device, includes a display device for displaying the image.

The display device includes a display panel, such as an organic light-emitting diode (OLED) display panel or a liquid crystal display (LCD) panel. A light-emitting display panel may include light-emitting elements, such as light-emitting diodes (LEDs), and examples of the LEDs include organic light-emitting diodes (OLEDs) using an organic material as a fluorescent material and inorganic light-emitting diodes using an inorganic material as a fluorescent material.

The display device further includes a gate driving circuit, a data driving circuit, and a timing controller. The display panel includes data lines, gate lines, and pixels, which are formed at the intersections between the data lines and the gate lines. The pixels use thin-film transistors as switching elements and, thus, receive data voltages from the data lines when gate signals are applied to the gate lines. The pixels emit light at a brightness (e.g., a predetermined brightness) in accordance with the data voltages.

Recently, display devices capable of displaying an image at a high resolution, such as ultra-high definition (UHD) resolution, have been developed. In a high-resolution display device, as the number of pixels increases, driving voltages applied to pixels may not be uniform, and relatively low voltages may be applied to some of the pixels.

### SUMMARY

To address the aforementioned problems, embodiments of the disclosure provide a display device including electrode patterns having the same potential as a voltage line and further including first-type pixels in which a common electrode is connected to the electrode patterns and second-type pixels in which the common electrode is not connected to the electrode patterns.

Embodiments of the disclosure also provide a display device including pixels in which a common electrode is connected to electrode patterns in a display area and pixels in which the common electrode is connected to electrode patterns in a non-display area.

It should be noted that aspects and features of the disclosure are not limited thereto and other aspects and features, which are not mentioned herein, will be apparent to those of ordinary skill in the art from the following description.

According to an embodiment of the disclosure, a display device has a display area and a non-display area extending around the display area. The display device includes: a plurality of pixels in the display area; a first voltage line in the display area; and a second voltage line in the non-display area. Each of the pixels includes an electrode pattern connected to the first voltage line, a pixel-defining film on the electrode pattern, an emission layer on the pixel-defining film, and a common electrode on the emission layer. The pixels include first-type pixels in which the common electrode and the electrode pattern are connected through an opening (e.g., an opening hole) formed in the pixel-defining film and exposing part of the electrode pattern and second-type pixels in which the opening (e.g., the opening hole) is not formed and the common electrode and the electrode pattern are not connected. The first-type pixels and the second-type pixels are adjacent to each other.

The display device may further include a sub-electrode pattern in the non-display area and connected to the second voltage line, and the pixels may further include third-type pixels in which the common electrode is connected to the sub-electrode pattern.

The third-type pixels may be spaced apart from the first-type pixels, and at least one of the second-type pixels may be between the first-type pixels and the third-type pixels.

A plurality of the first-type pixels may be spaced apart from one another, and the second-type pixels may be between the plurality of spaced apart first-type pixels.

A plurality of the third-type pixels may be spaced apart from one another, and the third-type pixels may be between the plurality of spaced apart third-type pixels.

The third-type pixels may be on at least one side of the display area, and the first-type pixels may be on the inside of the display area and spaced apart from the third-type pixels.

At least one of the first-type pixels may be between the third-type pixels.

The display area may have a plurality of pixel columns in which the pixels are arranged along a first direction, and the pixel columns may have a first pixel column including at least one of the first-type pixels and a second pixel column including the second-type pixels.

The first-type pixels and the third-type pixels may not be in the second pixel column.

The pixel columns may also have a third pixel column including at least one of the first-type pixels and at least one of the third-type pixels.

The third pixel column may further include at least one of the second-type pixels between the at least one of the first-type pixels and the at least one of the third-type pixels.

The pixel columns may also have a fourth pixel column including at least one of the second-type pixels between the first-type pixels, between the third-type pixels, or between the first-type pixels and the third-type pixels, and a number of second-type pixels between the first-type pixels and the third-type pixels in the third pixel column may differ from a number of the second-type pixels between the first-type pixels and the third-type pixels in the fourth pixel column.

The display area may have a plurality of pixel rows in which the pixels are arranged in a second direction intersecting the first direction, and the pixel rows may have a first pixel row including at least one of the first-type pixels and a second pixel row including at least one of the second-type pixels.

The first pixel row may further include at least one of the third-type pixels and at least one of the second-type pixels between the at least one of the third-type pixels and the at least one of the first-type pixels.

A first-type pixel area where the first-type pixels are arranged may be defined in the display area, and at least one side of the first-type pixel area may be spaced apart from the non-display area.

A size of the first-type pixel area may be smaller than a size of the display area.

Each of the pixels may further include at least one pixel electrode in the same layer as, but spaced apart from, the electrode pattern, and the emission layer may be between the pixel-defining film and the common electrode.

The pixel-defining film may have an opening exposing part of the pixel electrode, and in the opening, the emission layer may be between the common electrode and the pixel electrode, but not on part of the electrode pattern exposed by the opening hole.

According to an embodiment of the disclosure, a display device has a display area and a non-display area. The display device includes: a data conductive layer including a first voltage line in the display area and a second voltage line in the non-display area; a passivation film on the data conductive layer and covering the first and second voltage lines; a planarization film on the passivation film; a pixel electrode layer on the planarization film and including: an electrode pattern in the display area and connected to the first voltage line; and a sub-electrode pattern in the non-display area and connected to the second voltage line; a pixel-defining film on the planarization film and the electrode pattern; an emission layer on the pixel-defining film; and a common electrode on the emission layer and connected to the sub-electrode pattern. The electrode pattern includes a first electrode pattern not connected to the common electrode and a second electrode pattern connected to the common electrode.

The pixel-defining film may have an opening (e.g., an opening hole) exposing part of the second electrode pattern, and the second electrode pattern may be connected to the common electrode through the opening (e.g., the opening hole).

Details of other embodiments are included in the detailed description and the accompanying drawings.

According to embodiments of the disclosure, a display device includes a plurality of pixels in which electrode patterns have the same potential as voltage lines. The pixels may include first-type pixels in which a common electrode is connected to electrode patterns through openings (e.g., opening holes) exposing the electrode patterns, second-type pixels in which the common electrode is not connected to the electrode patterns, and third-type pixels in which the common electrode is connected to electrode patterns in a non-display area.

Thus, the display device can not only suppress a voltage drop in the common electrode but also reduces the number of first-type pixels including opening holes and reduces or minimizes the period of laser irradiation processes for forming the opening holes due to the presence of the third-type pixels.

The aspects and features according to embodiments of the disclosure are not limited to those described above, and more various aspects and features are included in this disclosure.

### BRIEF DESCRIPTION OF DRAWINGS

FIG. 1 is a plan view of a display device according to an embodiment of the disclosure.

FIG. 2 is a cross-sectional view of the display device according to an embodiment of the disclosure.

FIG. 3 is a schematic layout view of a circuit layer of a first display substrate of the display device according to an embodiment of the disclosure.

FIG. 4 is an equivalent circuit diagram of a pixel of the display device according to an embodiment of the disclosure.

FIG. 5 is a layout view of a pixel of the display device according to an embodiment of the disclosure.

FIG. 6 is a layout view illustrating a semiconductor layer and conductive layers included in the pixel shown in FIG. 5.

FIG. 7 is a layout view illustrating the conductive layers included in the pixel shown in FIG. 5.

FIG. 8 is a cross-sectional view taken along the lines IXa-IXa′ and IXb-IXb′ of FIG. 5.

FIG. 9 is an enlarged view of an opening area in FIG. 5.

FIG. 10 is a cross-sectional view taken along the line Xa-Xa′ of FIG. 9.

FIG. 11 is a plan view illustrating the layout of pixels in the display device according to an embodiment of the disclosure.

FIG. 12 is an enlarged view of an opening area of a second-type pixel of the display device according to an embodiment of the disclosure.

FIG. 13 is a cross-sectional view taken along the line Xb-Xb′ of FIG. 12.

FIG. 14 is an enlarged view of an opening area of a third-type pixel and part of a non-display area of the display device according to an embodiment of the disclosure.

FIG. 15 is a cross-sectional view taken along the line Xc-Xc′ of FIG. 14.

FIG. 16 is a schematic view illustrating the layout of pixels in the display device according to an embodiment of the disclosure.

FIGS. 17 through 20 are schematic views illustrating the layout of pixels in display devices according to other embodiments of the disclosure.

### DETAILED DESCRIPTION

The disclosure will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the invention. Similarly, the second element could also be termed the first element.

In the figures, dimensions of the various elements, layers, etc. may be exaggerated for clarity of illustration. As used herein, the term “and/or” includes any and all combinations of one or more of the associated listed items. Further, the use of “may” when describing embodiments of the present disclosure relates to “one or more embodiments of the present disclosure.” Expressions, such as “at least one of,” when preceding a list of elements, modify the entire list of elements and do not modify the individual elements of the list. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing particular embodiments of the present disclosure and is not intended to be limiting of the described embodiments of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Hereinafter, embodiments will be described with reference to the accompanying drawings.

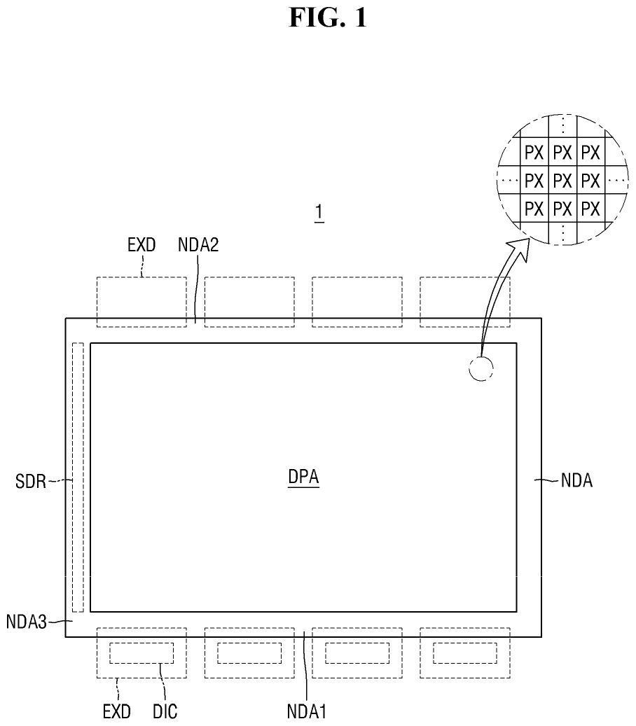

FIG. 1 is a plan view of a display device according to an embodiment of the disclosure.

A display device 1 may refer to all types of electronic devices that provide (e.g., include) a display screen. Examples of the display device 1 may include a television (TV), a notebook computer, a monitor, an electronic billboard, a mobile phone, a smartphone, a tablet personal computer (PC), an electronic watch, a smartwatch, a watchphone, a mobile communication terminal, an electronic notebook, an e-book, a portable multimedia player (PMP), a navigation device, a game console, a digital camera, and an Internet of things (IoT) device that can provide a display screen.

The display device 1 is illustrated as being a TV. The display device 1 may have a high- or an ultrahigh resolution, such as High Definition (HD), Ultra-High Definition (UHD), 4K, or 8K, but the disclosure is not limited thereto.

The display device 1 may be classified in various manners according to how it displays an image. Examples of the display device 1 include an organic light-emitting diode (OLED) display device, an inorganic electroluminescent (EL) display device, a quantum-dot light-emitting diode (QED) display device, a light-emitting diode (LED) display device, a plasma display panel (PDP) display device, a field emission display (FED) device, a cathode ray tube (CRT) display device, a liquid crystal display (LCD) device, and an electrophoretic display (EPD) device. The display device 1 will hereinafter be described as being, for example, an OLED display device, and an OLED display device will hereinafter be referred to simply as the display device 1 unless specified otherwise. However, the display device 1 is not particularly limited to being an OLED display device and may be applicable to various other display devices as would be understood by those skilled in the art.

The display device 1 may have a rectangular shape in a plan view. When the display device 1 is a TV, the long sides of the display device 1 may be aligned in a horizontal direction, but the disclosure is not limited thereto. in other embodiments, the long sides of the display device 1 may be aligned in a vertical direction, or the display device 1 may be installed to be rotatable such that the long sides of the display device 1 may be aligned variably either in the horizontal direction or in the vertical direction.

The display device 1 may have a display area DPA and a non-display area NDA. The display area DPA may be an active area where the display of an image is conducted (e.g., where an image is displayed). The display area DPA may have a similar shape to the display device 1, i.e., a rectangular shape in FIG. 1, in a plan view.

The display area DPA may include a plurality of pixels PX. The pixels PX may be arranged in row and column directions. The pixels PX may have a rectangular or square shape in a plan view, but the disclosure is not limited thereto. In other embodiments, the pixels PX may have a rhombus shape inclined with respect to a side of the display device 1. The pixels PX may include pixels PX of (e.g., displaying) various colors. For example, the pixels PX may include first-color (or red) pixels PX, second-color (or green) pixels PX, and third-color (or blue pixels) PX, but the disclosure is not limited thereto. The pixels PX of the various colors may be alternately arranged in a stripe fashion or a PenTile® (a registered trademark of Samsung Display Co., Ltd.,) (also known as RGBG matrix) fashion.

The non-display area NDA may be disposed around the display area DPA. The non-display area NDA may surround (e.g., may extend around the periphery of) the entire display area DPA or part of the display area DPA. The display area DPA may have a rectangular shape, and the non-display area NDA may be disposed adjacent to four sides of the display area DPA. The non-display area NDA may form the bezel of the display device 1.

In the non-display area NDA, driving circuits or driving elements for driving the display area DPA may be disposed. In one embodiment, a pad unit may be provided in a first non-display area NDA1, which is disposed adjacent to a first long side (the lower side in FIG. 1) of the display device 1, and a second non-display area NDA2, which is disposed adjacent to a second long side (the upper side in FIG. 1) of the display device 1, and external devices EXD may be mounted on pad electrodes of the pad unit. Examples of the external devices EXC include a connecting film, a printed circuit board, a driver chip DIC, a connector, and a wire connecting film. In a third non-display area NDA3, which is disposed adjacent to a first short side (the left side in FIG. 1) of the display device 1, a scan driver SDR, which is formed directly on a display substrate of the display device 1, may be disposed.

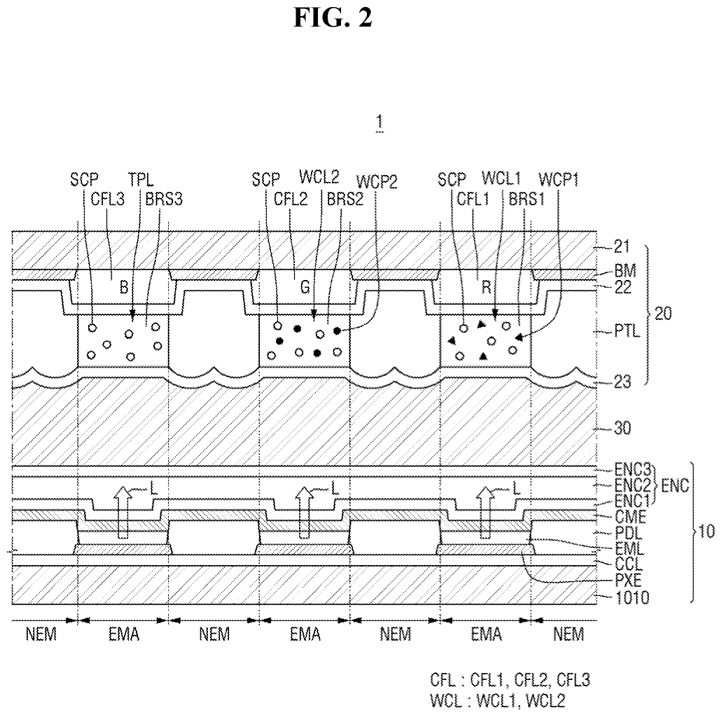

FIG. 2 is a cross-sectional view of the display device according to an embodiment of the disclosure.

FIG. 2 illustrates, as an example of the display device 1, a front emission display device emitting light L not in a direction toward a first substrate 1010 where emission layers EML are formed but in the opposite direction (i.e., in a direction toward a second substrate 21). The display device 1 is not limited thereto.

Referring to FIG. 2, the display device 1 may include the emission layer EML, an encapsulation film ENC, which covers the emission layers EML, and a color control structure (WCL, TPL, and CFL), which is disposed above the encapsulation film ENC. In one embodiment, the display device 1 may further include a first display substrate 10 and a second display substrate 20, which is opposite to the first display substrate 10. The emission layers EML, the encapsulation film ENC, and the color control structure (WCL, TLP, and CFL) may be included in one of the first and second display substrates 10 and 20.

For example, the first display substrate 10 may include the first substrate 1010, the emission layers EML, which are disposed on a first surface of the first substrate 1010, and the encapsulation film ENC, which is disposed on the emission layers EML. Also, for example, the second display substrate 20 may include the second substrate 21 and the color control structure (WCL, TPL, and CFL), which is disposed on a first surface of the second substrate 21 that faces the first substrate 1010. The color control structure (WCL, TPL, and CFL) may include color filter layers CFL and a wavelength conversion layer WCL. The color control structure (WCL, TPL, and CFL) may further include a light-transmitting layer TPL, which is disposed on the same level as the wavelength conversion layer WCL in some of the pixels PX.

A filler layer 30 may be disposed between the encapsulation film ENC and the color control structure (WCL, TPL, and CFL). The filler layer 30 may fill the space between the first and second display substrates 10 and 20 and may bond the first and second display substrates 10 and 20 together.

The first substrate 1010 of the first display substrate 10 may be an insulating substrate. The first substrate 1010 may include a transparent material. For example, the first substrate 1010 may include a transparent insulating material, such as glass or quartz. The first substrate 1010 may be a rigid substrate, but the disclosure is not limited thereto. In some embodiments, the first substrate 1010 may include plastic, such as polyimide, and may have flexibility, such as bendability, foldability, and rollability.

A plurality of pixel electrodes PXE may be disposed on the first surface of the first substrate 1010. The pixel electrodes PXE may be disposed in respective pixels PX. Pixel electrodes PXE in a pair of adjacent pixels PX may be separated from each other. A circuit layer CCL, which drives the pixels PX, may be disposed on the first substrate 1010. The circuit layer CCL may be disposed between the first substrate 1010 and the pixel electrodes PXE. The circuit layer CCL will be described later in more detail.

The pixel electrodes PXE may be the first electrodes (e.g., the anode electrodes) of light-emitting diodes (LEDs). The pixel electrodes PXE may have a structure in which a high-work function material layer of, for example, indium tin oxide (ITO), indium zinc oxide (IZO), zinc oxide (ZnO), or indium oxide (In₂O₃), and a reflective material layer of, for example, silver (Ag), magnesium (Mg), aluminum (Al), platinum (Pt), lead (Pb), gold (Au), nickel (Ni), neodymium (Nd), iridium (Ir), chromium (Cr), lithium (Li), calcium (Ca), or a mixture thereof, are stacked. The high-work function material layer may be disposed above the reflective material layer, close to the emission layers EML. The pixel electrodes PXE may have a multilayer structure of ITO/Mg, ITO/MgF, ITO/Ag, or ITO/Ag/ITO, but the disclosure is not limited thereto.

A pixel-defining film PDL may be disposed on the first surface of the first substrate 1010 along the boundaries of each of the pixels PX. The pixel-defining film PDL may be disposed on the pixel electrodes PXE and may include openings that expose the pixel electrodes PXE. Due to the pixel-defining film PDL and the openings in the pixel-defining film PDL, emission areas EMA and non-emission areas NEM may be defined. The pixel-defining film PDL may include an organic insulating material, such as an acrylic resin, an epoxy resin, a phenolic resin, a polyamide resin, a polyimide resin, an unsaturated polyester resin, a polyphenylene resin, a polyphenylene sulfide resin, or benzocyclobutene (BCB). The pixel-defining film PDL may include an inorganic material.

The emission layers EML may be disposed on the pixel electrodes PXE exposed by the pixel-defining film PDL. In an embodiment in which the display device 1 is an OLED display device, each of the emission layers EML may include organic layers that include an organic material. The organic layers may include organic light-emitting layers and may further include hole injection/transport layers and/or electron injection/transport layers as auxiliary layers for assisting with (e.g., improving) the emission of light. In an embodiment in which the display device 1 is an LED display device, the emission layers EML may include an inorganic material, such as an inorganic semiconductor.

In some embodiments, each of the emission layers EML may have a tandem structure including a plurality of organic light-emitting layers, which are disposed to overlap with one another in a thickness direction, and charge-generating layers, which are disposed between the organic light-emitting layers. The plurality of organic light-emitting layers may emit light of the same wavelength or light of different wavelengths. At least some of the layers of each of the emission layers EML may be separated from the corresponding layers of their respective neighboring emission layers EML.

In one embodiment, the wavelength of light emitted by the emission layers EML may be uniform for all the pixels PX. For example, the emission layers EML of the pixels PX may all emit blue light or ultraviolet (UV) light, and the pixels PX may display their respective colors due to the presence of the wavelength conversion layer WCL of the color control structure (WCL, TPL, and CFL).

In another embodiment, the wavelength of light emitted by the emission layers EML may vary from the first-color pixel PX to the second-color pixel PX to the third-color pixel PX. For example, the emission layer EML of the first-color pixel PX may emit light of the first color, the emission layer EML of the second-color pixel PX may emit light of the second color, and the emission layer EML of the third-color pixel PX may emit light of the third color. The emission layers EML may be disposed on the entire surfaces of the pixel electrodes PXE and on the entire surface of the pixel-defining film PDL, but the disclosure is not limited thereto. In other embodiments, the emission layers EML may be disposed to correspond to the openings of the pixel-defining film PDL, and as will be described later, the emission layers EML may not be disposed in part in regions other than the openings of the pixel-defining film PDL.

A common electrode CME may be disposed on the emission layers EML. The common electrode CME may be in contact not only with the emission layers EML but also with the top surface of the pixel-defining film PDL.

Parts of the common electrode CME may all be connected without regard to the pixels PX. The common electrode CME may be a full electrode (e.g., a single or continuous electrode) disposed over the entire surface of the first substrate 110 without distinguishing the pixels PX. The common electrode CME may correspond to the second electrodes (e.g., the cathode electrodes) of LEDs.

The common electrode CME may include a low-work function material layer of Li, Ca, LiF/Ca, LiF/AI, Al, Mg, Ag, Pt, Pd, Ni, Au Nd, Ir, Cr, BaF, Ba, or a compound or mixture thereof, for example, the mixture of Ag and Mg. The common electrode CME may further include a transparent metal oxide layer disposed on the low-work function material layer.

The pixel electrodes PXE, the emission layers EML, and the common electrode CME may form light-emitting elements (e.g., OLEDs). Light may be emitted upwardly from the emission layers EML through the common electrode CME.

The encapsulation film ENC may be disposed on the common electrode CME. The encapsulation film ENC may include at least one layer. For example, the encapsulation film ENC may include a first inorganic film ENC1, an organic film ENC2, and a second inorganic film ENC3. The first and second inorganic films ENC1 and ENC3 may include silicon nitride, silicon oxide, or silicon oxynitride. The organic film ENC2 may include an organic insulating material, such as an acrylic resin, an epoxy resin, a phenolic resin, a polyamide resin, a polyimide resin, an unsaturated polyester resin, a polyphenylene resin, a polyphenylene sulfide resin, or benzocyclobutene (BCB).

The second display substrate 20 may be disposed to face the encapsulation film ENC from above the encapsulation film ENC. The second substrate 21 of the second display substrate 20 may include a transparent material. The second substrate 21 may include a transparent insulating material, such as glass or quartz. The second substrate 21 may be a rigid substrate, but the disclosure is not limited thereto. In other embodiments, the second substrate 21 may include plastic, such as polyimide, and may have flexibility, such as bendability, foldability, and rollability.

The same substrate as the first substrate 1010 may be used as the second substrate 21, but the second substrate 21 may include a different material, thickness, or transmittance from the first substrate 1010. For example, the second substrate 21 may have a higher transmittance than the first substrate 1010. Also, for example, the second substrate 21 may be thicker or thinner than the first substrate 1010.

A light-blocking member BM may be disposed on the first surface of the second substrate 21 that faces the first substrate 1010, along the boundaries of each of the pixels PX. The light-blocking member BM may overlap the pixel-defining film PDL of the first display substrate 10 and may be disposed in the non-emission areas NEM. The light-blocking member BM may have openings that expose parts of the first surface of the second substrate 21 that overlap the emission areas EMA. The light-blocking member BM may be formed in a lattice shape in a plan view.

The light-blocking member BM may include an organic material. The light-blocking member BM can reduce any color distortion caused by the reflection of external light by absorbing external light. Also, the light-blocking member can prevent or substantially prevent light emitted from the emission layer EML of one pixel PX from infiltrating into the emission layer EML of another pixel PX (or from being emitted through an emission area EMA of another pixel PX).

In one embodiment, the light-blocking member BM may absorb all visible wavelengths. The light-blocking member BM may include a light-absorbing material. For example, the light-blocking member BM may be formed of a material that can be used as a black matrix.

The color filter layers CFL may be disposed on the first surface of the second substrate 21 where the light-blocking member BM is disposed. The color filter layers

CFL may be disposed on parts of the first surface of the second substrate 21 exposed by the openings of the light-blocking member BM. The color filter layers CFL may also be disposed on parts of the light-blocking member BM.

The color filter layers CFL may include a first color filter layer CFL1, which is disposed in the first-color pixel PX, a second color filter layer CFL2, which is disposed in the second-color pixel PX, and a third color filter layer CFL3, which is disposed in the third-color filter PX. Each of the color filter layers CFL may include a colorant, such as a pigment or dye, capable of absorbing particular wavelengths. The first color filter layer CFL1 may be a red filter layer, the second color filter layer CFL2 may be a green filter layer, and the third color filter layer CFL3 may be a blue filter layer. FIG. 2 illustrates that a pair of adjacent color filter layers CFL are spaced apart from each other over the light-blocking member BM, but the color filter layers CFL may at least partially overlap each other over the light-blocking member BM.

A first capping layer 22 may be disposed on the color filter layers CFL. The first capping layer 22 may protect the color filter layers CFL from being damaged or polluted by impurities, such as moisture or air from the outside. Also, the first capping layer 22 may prevent the colorants of the color filter layers CFL from diffusing into other elements.

The first capping layer 22 may be in direct contact with first surfaces (e.g., the bottom surfaces in FIG. 2) of the color filter layers CFL. The first capping layer 22 may be formed of an inorganic material. For example, the first capping layer 22 may include silicon nitride, aluminum nitride, zirconium nitride, titanium nitride, hafnium nitride, tantalum nitride, silicon oxide, aluminum oxide, titanium oxide, tin oxide, or silicon oxynitride.

A partition PTL may be disposed on the first capping layer 22. The partition PTL may be located in the non-emission areas NEM. The partition PTL may be disposed to overlap the light-blocking member BM. The partition PTL may have openings that expose the color filter layers CFL. The partition PTL may be formed to include a photosensitive organic material, but the disclosure is not limited thereto. The partition PTL may further include a light-blocking material.

The wavelength conversion layer WCL and the light-transmitting layer TPL may be disposed in the spaces exposed by the openings in the partition PTL. The wavelength conversion layer WCL and the light-transmitting layer TPL may be formed by an inkjet process using the partition PTL as a bank, but the disclosure is not limited thereto.

In an embodiment in which the emission layers EML of the pixels PX emit light of the third color, the wavelength conversion layer WCL may include a first wavelength conversion pattern WCL1, which is disposed in the first-color pixel PX, and a second wavelength conversion pattern WCL2, which is disposed in the second-color pixel PX. The light-transmitting layer TPL may be disposed in the third-color pixel PX.

The first wavelength conversion pattern WCL1 may include a first base resin BRS1 and a first wavelength conversion material WCP1, which is disposed in the first base resin BRS1. The second wavelength conversion pattern WCL2 may include a second base resin BRS2 and a second wavelength conversion material WCP2, which is disposed in the second base resin BRS2. The light-transmitting layer TPL may include a third base resin BRS3 and a scatterer SCP, which is disposed in the third base resin BRS3.

The first, second, and third base resins BRS1, BRS2, and BRS3 may include a light-transmitting organic material. For example, the first, second, and third base resins BRS1, BRS2, and BRS3 may include an epoxy resin, an acrylic resin, a cardo resin, or an imide resin. The first, second, and third base resins BRS1, BRS2, and BRS3 may all be formed of the same material, but the disclosure is not limited thereto.

The scatterer SCP may be metal oxide particle or organic particles. For example, the metal oxide may be titanium oxide (TiO₂), zirconium oxide (ZrO₂), aluminum oxide (Al₂O₃), indium oxide (In₂O₃), zinc oxide (ZnO), or tin oxide (SnO₂), and the material of the organic particles may be an acrylic resin or a urethane resin.

The first wavelength conversion material WCP1 may convert the third color into the first color, and the second wavelength conversion material WCP2 may convert the third color into the second color. The first and second wavelength conversion materials WCP1 and WCP2 may be quantum dots, quantum rods, or phosphors. The quantum dots may include group IV nanocrystals, group II-VI compound nanocrystals, group III-V compound nanocrystals, group IV-VI nanocrystals, or a combination thereof. Each of the first and second wavelength conversion patterns WCL1 and WCL2 may further include the scatterer SCP, which improves the efficiency of wavelength conversion.

The light-transmitting layer TPL, which is disposed in the third-color pixel PX, may transmit therethrough light of the third color incident thereupon from the emission layer EML of the third-color pixel PX while maintaining (e.g., without changing or substantially changing) the wavelength of the incident light. The scatterer SCP of the light-transmitting layer TPL may control the path of light emitted through the light-transmitting layer TPL. The light-transmitting layer TPL may not include a wavelength conversion material.

A second capping layer 23 is disposed on the wavelength conversion layer WCL and the light-transmitting layer TPL. The second capping layer 23 may be formed of an inorganic material. The second capping layer 23 may include one selected from the aforementioned materials of the first capping layer 22. The first and second capping layers 22 and 23 may be formed of the same material, but the disclosure is not limited thereto.

The filler layer 30 may be disposed between the first and second display substrates 10 and 20. The filler layer 30 may fill the space between the first and second display substrates 10 and 20 and may also bond the first and second display substrates 10 and 20 together. The filler layer 30 may be disposed between the encapsulation film ENC of the first display substrate 10 and the second capping layer 23 of the second display substrate 20. The filler layer 30 may be formed of a silicon (Si)-based organic material or an epoxy-based organic material, but the disclosure is not limited thereto.

The circuit layer CCL of the display device 1 will hereinafter be described.

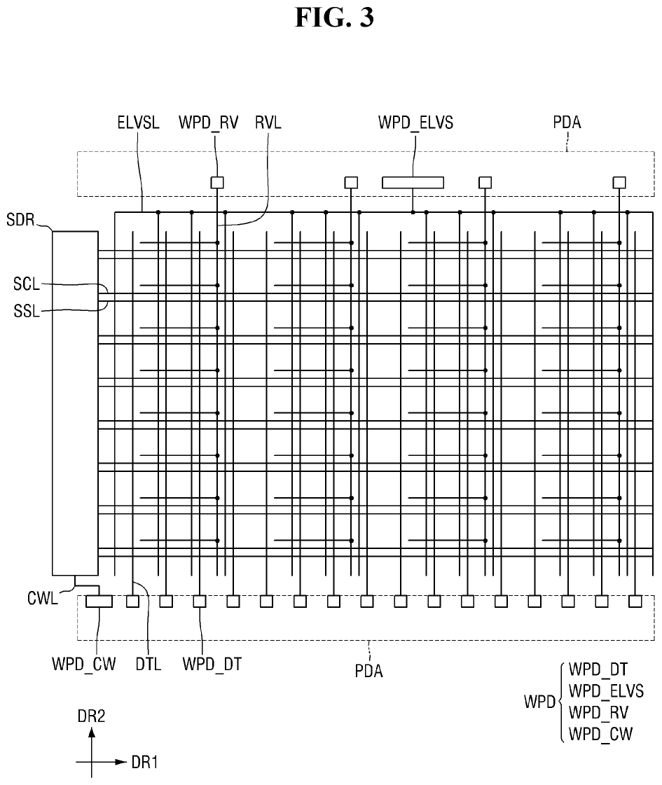

FIG. 3 is a layout view illustrating a first display substrate of the display device shown in FIG. 1.

Referring to FIG. 3, a plurality of lines are disposed on the first substrate 1010. The plurality of lines may include scan lines SCL, sensing lines SSL, data lines DTL, reference voltage lines RVL, first power supply lines ELVDL, and second power supply lines ELVSL. The first power supply lines ELVDL are not illustrated, and only the second power supply lines ELVSL are illustrated. The first power supply lines ELVDL may be arranged in the same manner as the second power supply lines ELVSL.

The scan lines SCL and the sensing lines SSL may extend in a first direction DR1. The scan lines SCL and the sensing lines SSL may be connected to the scan driver SDR. The scan driver SDR may include driving circuits that form the circuit layer CCL. The scan driver SDR may be disposed in the third non-display area NDA3 on the first substrate 1010, but the disclosure is not limited thereto. In other embodiments, the scan driver SDR may be disposed in a fourth non-display area NDA4, which is disposed opposite to the third non-display area NDA3, or in both the third and fourth non-display areas NDA3 and NDA4. The scan driver SDR may be connected to a signal connecting line CWL, and at least one end of the signal connecting line CWL may form pads WPD_CW in the first non-display area NDA1 and/or in the second non-display area NDA2 to be connected to the external devices EXD shown in FIG. 1.

The data lines DTL and the reference voltage lines RVL may extend in a second direction DR2 that crosses (e.g., intersects) the first direction DR1. The second power supply lines ELVSL may include parts (or portions) that extend in the second direction DR2. The second power supply lines ELVSL may include parts (or portions) that extend in the first direction DR1. The second power supply lines ELVSL may have a mesh structure, but the disclosure is not limited thereto.

Wire pads WPD may be disposed at least at first ends of the data lines DTL, the reference voltage lines RVL, and the second power supply lines ELVSL. The wire pads WPD may be disposed in the non-display area NDA. In one embodiment, wire pads WPD_DT of the data lines DTL (hereinafter, the data pads WPD_DT) may be disposed in the first non-display area NDA1, and wire pads WPD_RV of the reference voltage lines RVL (hereinafter, the reference voltage pads WPD_RV) and a wire pad WPD_ELVS of the second power supply lines ELVSL (hereinafter, the power supply pad WPD_ELVS) may be disposed in the second non-display area NDA2. In another embodiment, the data pads WPD_DT, the reference voltage pads WPD_RV, and the second power supply pad WPD_ELVS may all be disposed in the same area, for example, in the first non-display area NDA1. The external devices EXD shown in FIG. 1 may be mounted on the wire pads WPD. The external devices EXD may be mounted on the wire pads WPD via anisotropic conductive films or through ultrasonic bonding.

The pixels PX on the first substrate 1010 may include pixel driving circuits. The plurality of lines may pass through or pass by the pixels PX to apply driving signals to the pixel driving circuits. Each of the pixel driving circuits may include transistors and capacitors. The numbers of transistors and capacitors in each of the pixel driving circuits may vary. The pixel driving circuits will hereinafter be described as having, for example, a “3T1C” structure including three transistors and one capacitor, but the disclosure is not limited thereto. That is, various modified pixel structures, such as a “2T1C”, “7T1C”, or “6T1C” structure, can also be applied to the pixel driving circuits of the pixels PX.

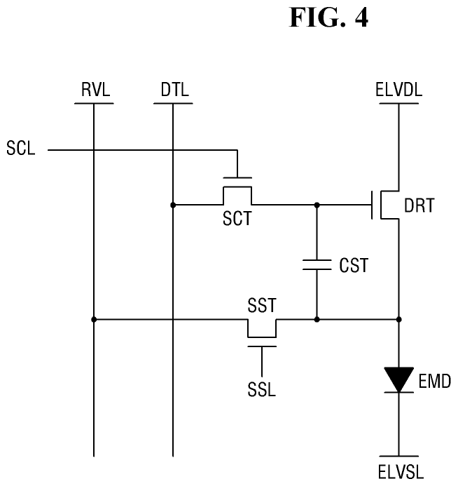

FIG. 4 is an equivalent circuit diagram of a pixel PX of the display device shown in FIG. 1.

Referring to FIG. 4, the pixel PX includes a light-emitting element EMD, three transistors (DRT, SCT, and SST) and one storage capacitor CST.

The light-emitting element EMD emits light in accordance with a current applied thereto via a driving transistor DRT. The light-emitting element EMD may be implemented as an OLED, a micro-LED, ora nano-LED.

A first electrode (i.e., an anode electrode) of the light-emitting element EMD may be connected to the source electrode of the driving transistor DRT, and a second electrode (i.e., a cathode electrode) of the light-emitting element EMD may be connected to a second power supply line ELVSL, to which a low-potential voltage (or a second power supply voltage ELVS) lower than a high-potential voltage (or a first power supply voltage ELVD) supplied to a first power supply line ELVDL is supplied.

The driving transistor DRT may adjust a current that flows from the first power supply line ELVDL to the light-emitting element EMD in accordance with the difference between the gate and source voltages thereof. The gate electrode of the driving transistor DRT may be connected to a first source/drain electrode of a first switching transistor SCT, the source electrode of the driving transistor DRT may be connected to the first electrode of the light-emitting element EMD, and the drain electrode of the driving transistor DRT may be connected to the first power supply line ELVDL, to which the first power supply voltage ELVD is applied.

The first switching transistor SCT is turned on by a scan signal from a scan line SCL to connect a data line DTL to the gate electrode of the driving transistor DRT. The gate electrode of the first switching transistor SCT may be connected to the scan line SCL, a first source/drain electrode of the first switching transistor SCT may be connected to the gate electrode of the driving transistor DRT, and a second source/drain electrode of the first switching transistor SCT may be connected to the data line DTL.

A second switching transistor SST is turned on by a sensing signal from a sensing line SSL to connect a reference voltage line RVL to the source electrode of the driving transistor DRT. The gate electrode of the second switching transistor SST may be connected to the sensing line SSL, a first source/drain electrode of the second switching transistor SST may be connected to the reference voltage line RVL, and the second source/drain electrode of the second switching transistor SST may be connected to the source electrode of the driving transistor DRT.

In one embodiment, the first source/drain electrodes of the first and second switching transistors SCT and SST may be source electrodes, and the second source/drain electrodes of the first and second switching transistors SCT and SST may be drain electrodes. However, the disclosure is not limited to this embodiment. In other embodiments, the first source/drain electrodes of the first and second switching transistors SCT and SST may be drain electrodes, and the second source/drain electrodes of the first and second switching transistors SCT and SST may be source electrodes.

The storage capacitor CST may be formed between the gate electrode and the source electrode of the driving transistor DRT. The storage capacitor CST stores the difference between the gate voltage and the source voltage of the driving transistor DRT.

The driving transistor DRT and the first and second switching transistors SCT and SST may be formed as thin-film transistors (TFTs). FIG. 3 illustrates that the driving transistor DRT and the first and second switching transistors SCT and SST are formed as N-type metal-oxide semiconductor field-effect transistors (MOSFETs), but the disclosure is not limited thereto. In other embodiments, the driving transistor DRT and the first and second switching transistors SCT and SST may be formed as P-type MOSFETs. In some embodiments, some of the driving transistor DRT and the first and second switching transistors SCT and SST may be formed as N-type MOSFETS and the other transistor(s) may be formed as P-type MOSFETs

The structure of one pixel of the display device 1 will hereinafter be described with reference to other drawings.

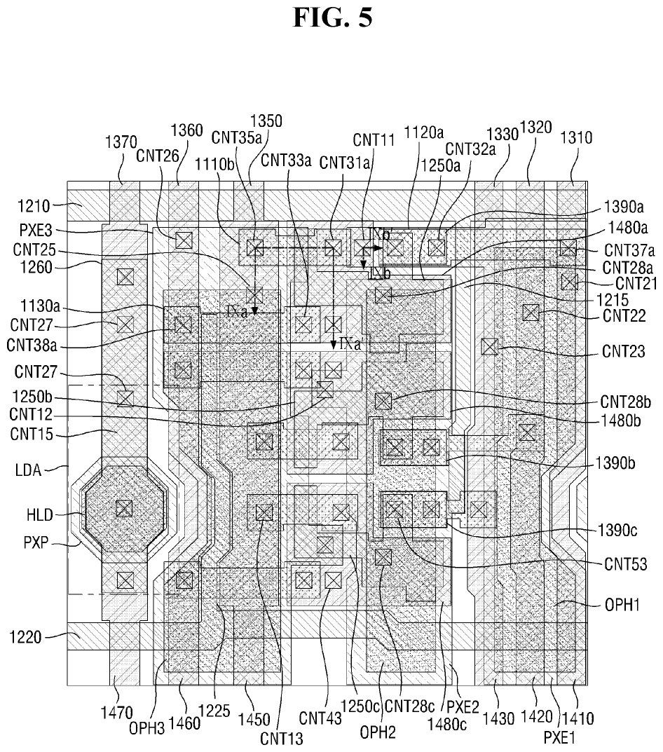

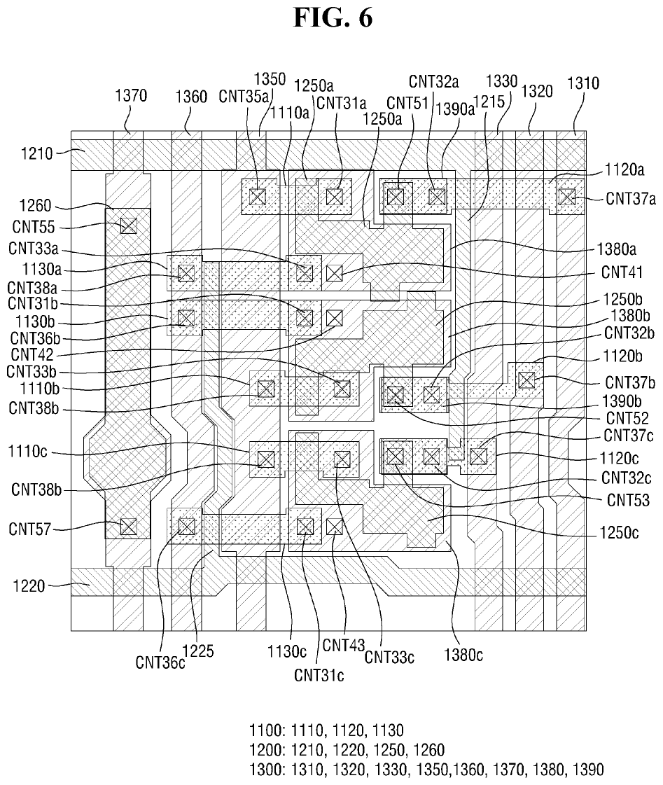

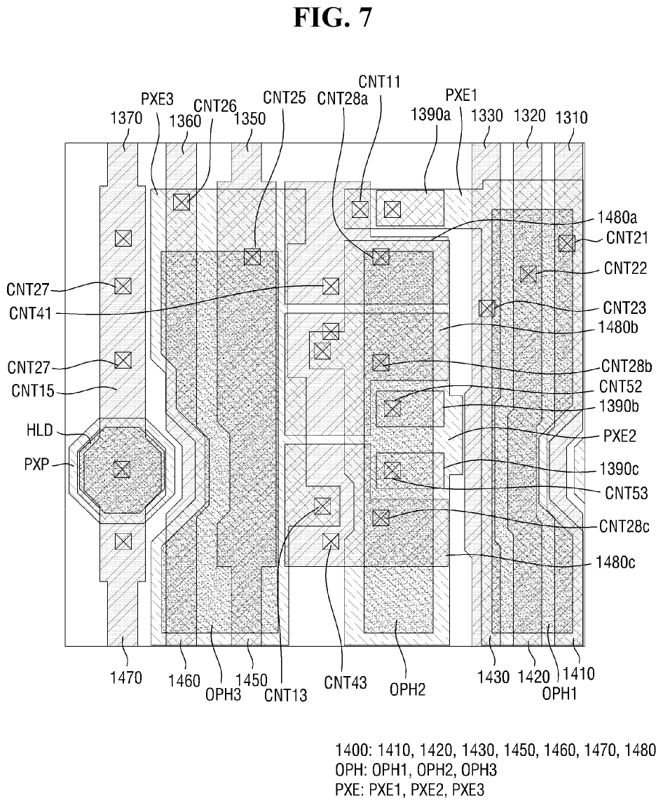

FIG. 5 is a layout view of a pixel of the display device according to an embodiment of the disclosure. FIG. 6 is a layout view illustrating a semiconductor layer and conductive layers included in the pixel shown in FIG. 5. FIG. 7 is a layout view illustrating the conductive layers included in the pixel shown in FIG. 5.

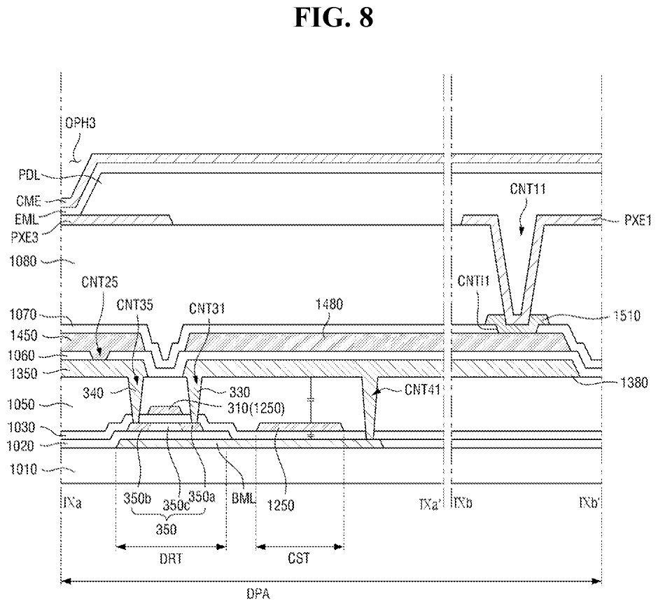

Referring to FIGS. 5 through 7, the display device 1 may include a semiconductor layer 1100 and a plurality of conductive layers (1200, 1300, and 1400). The display device 1 may include a plurality of insulating layers (1020, 1030, 1050, 1060, 1070, and 1080, as illustrated in FIG. 8), which are disposed between the semiconductor layer 1100 and the conductive layers (1200, 1300, and 1400). The conductive layers (1200, 1300, and 1400) may include a gate conductive layer 1200, a first data conductive layer 1300, and a second data conductive layer 1400, and the insulating layers (1020, 1030, 1050, 1060, 1070, and 1080) may include a buffer film 1020, a gate insulating film 1030, a first interlayer insulating film 1050, a first passivation film 1060, a second passivation film 1070, and a planarization film 1080.

FIG. 5 illustrates a layout view of a stack of the semiconductor layer 1100 and the conductive layers (1200, 1300, and 1400) in a pixel of the display device 1. FIG. 6 illustrates a layout view of a stack of the semiconductor layer 1100, the gate conductive layer 1200, and the first data conductive layer 1300, and FIG. 7 illustrates a layout view of a stack of the first data conductive layer 1300, the second data conductive layer 1400, the pixel electrodes PXE, and the pixel-defining film PDL.

A pixel PX of the display device 1 may include a plurality of subpixels. Part of the pixel PX illustrated in FIGS. 5 through 7 may form a first subpixel, another part of the pixel PX may form a second subpixel, and yet another part of the pixel PX may form a third subpixel. As illustrated in the equivalent circuit diagram shown in FIG. 4, each of the first, second, and third subpixels may include a plurality of transistors, a storage capacitor, and multiple lines. FIGS. 5 through 7 illustrate that there are provided three subpixels, each including a driving transistor DRT, a first switching transistor SCT, a second switching transistor SST, and a storage capacitor CST. Also, the first, second, and third subpixels may be electrically connected to different data lines and the same power supply line. Multiple layers disposed in the pixel PX or each of the subpixels of the display device 1 will hereinafter be described. For convenience, layers disposed in one subpixel will hereinafter be described, and any redundant descriptions of layers disposed in another subpixel will be simplified.

Referring to FIGS. 5 and 6, the semiconductor layer 1100 is disposed on the first substrate 1010. The buffer film 1020 (see, e.g., FIG. 8) may be disposed on the first substrate 1010, and the semiconductor layer 1100 may be disposed on the buffer film 1020. The semiconductor layer 1100 may include a plurality of first semiconductor layers 1110, a plurality of second semiconductor layers 1120, and a plurality of third semiconductor layers 1130. The first semiconductor layers 1110 may be the active layers of driving transistors DRT included in the pixel PX, the second semiconductor layers 1120 may be the active layers of first switching transistors SCT, and the third semiconductor layers 1130 may be the active layers of second switching transistors SST.

The first semiconductor layers 1110, the second semiconductor layers 1120, and the third semiconductor layers 1130 may extend in the first direction DR1, e.g., in a horizontal direction, and both ends of each of the first semiconductor layers 1110, the second semiconductor layers 1120, and the third semiconductor layers 1130 may be expanded to have a greater width. The gate electrodes of the driving transistors DRT, the first switching transistors SCT, and the second switching transistors SST may be formed in parts of the first semiconductor layers 1110, the second semiconductor layers 1120, and the third semiconductor layers 1130 that extend in the first direction DR1 and may overlap with the gate conductive layer 1200, and both expanded end parts of each of the first semiconductor layers 1110, the second semiconductor layers 1120, and the third semiconductor layers 1130 may be in contact with the first data conductive layer 1300 to form the source and drain electrodes of each of the driving transistors DRT, the first switching transistors SCT, and the second switching transistors SST. Both end parts of the semiconductor layer 1100 may be transformed in part into conductors and, thus, may form conductive regions (see, e.g., FIG. 8), and channel regions may be formed between the conductive regions see, e.g., FIG. 8).

The first semiconductor layers 1110 may include an 11^{th} semiconductor layer 1110a, which is positioned in an upper part of the pixel PX, and 12^{th} and 13^{th} semiconductor layers 1110b and 1110c, which are positioned near the center of the pixel PX. The 11^{th} semiconductor layer 1110a may be the active layer of a driving transistor DRT of a first subpixel, the 12^{th} semiconductor layer 1110b may be the active layer of a driving transistor DRT of a second subpixel, and the 13^{th} semiconductor layer 1110c may be the active layer of a driving transistor DRT of a third subpixel.

The first semiconductor layers 1110 may have a pattern shape extending in one direction. First sides of the first semiconductor layers 1110 may be in contact with parts of first conductive patterns 1380 of the first data conductive layer 1300, which will be described later, second sides of the first semiconductor layers 1110 may be in contact with parts of a first voltage line 1350, and the first semiconductor layers 1110 may overlap with parts of gate conductive patterns 1250 of the gate conductive layer 1200, which will be described later, between the first sides and the second sides thereof. Parts of the first data conductive layer 1300 that are in contact with the first sides of the first semiconductor layers 1110 may be the source electrodes of the driving transistors DRT, and parts of the first data conductive layer 1300 that are in contact with the second sides of the first semiconductor layers 1110 may be the drain electrodes of the driving transistors DRT. Parts of the gate conductive layer 1200 that overlap with the first semiconductor layers 1110, between the first sides and the second sides of the first semiconductor layers 1110, may be the gate electrodes of the driving transistors DRT.

The second semiconductor layers 1120 may be positioned on the right side of the center of the pixel PX. The second semiconductor layers 1120 may include 21^{st}, 22^{nd}, and 23^{rd} semiconductor layers 1120a, 1120b, and 1120c. The 21^{st} semiconductor layer 1120a may be the active layer of a first switching transistor SCT of the first subpixel, the 22^{nd} semiconductor layer 1120b may be the active layer of a first switching transistor SCT of the second subpixel, and the 23^{rd} semiconductor layer 1120c may be the active layer of a first switching transistor SCT of the third subpixel.

The second semiconductor layers 1120 may also have a pattern shape extending in one direction. First sides of the second semiconductor layers 1120 may be in contact with parts of second conductive patterns 1390 of the first data conductive layer 1300, which will be described later, and second sides of the second semiconductor layers 1120 may be in contact with parts of first data signal lines (1310, 1320, and 1330). The second semiconductor layers 1120 may overlap with parts of a scan signal line 1210 of the gate conductive layer 1200, which will be described later, between the first sides and the second sides thereof. Parts of the first data conductive layer 1300 that are in contact with the first sides of the second semiconductor layers 1120 may be the source electrodes of the first switching transistors SCT, and parts of the first data conductive layer 1300 that are in contact with the second sides of the second semiconductor layers 1120 may be the drain electrodes of the first switching transistors SCT. Parts of the gate conductive layer 1200 that overlap with the second semiconductor layers 1120, between the first sides and the second sides of the second semiconductor layers 1120, may be the gate electrodes of the first switching transistors SCT.

The second sides of the second semiconductor layers 1120 may be in contact with different first data signal lines (1310, 1320, and 1330). The 21^{st} semiconductor layer 1120a may be in contact with an 11^{th} data signal line 1310, the 22^{nd} semiconductor layer 1120b may be in contact with a 12^{th} data signal line 1320, and the 23^{rd} semiconductor layer 1120c may be in contact with a 13^{th} data signal line 1330. Because the second semiconductor layers 1120 are in contact with different first data signal lines (1310, 1320, and 1330), different data signals can be applied to different subpixels.

The third semiconductor layers 1130 may be positioned on the left side of the center of the pixel PX. The third semiconductor layers 1130 may include 31^{st}, 32^{nd}, and 33^{rd} semiconductor layers 1130a, 1130b, and 1130c. The 31^{st} semiconductor layer 1130a may be the active layer of a second switching transistor SST of the first subpixel, the 32^{nd} semiconductor layer 1130b may be the active layer of a second switching transistor SST of the second subpixel, and the 33^{rd} semiconductor layer 1130c may be the active layer of a second switching transistor SST of the third subpixel.

The third semiconductor layers 1130 may also have a pattern shape extending in one direction. First sides of the third semiconductor layers 1130 may be in contact with parts of the first conductive patterns 1380 of the first data conductive layer 1300, which will be described later, and second sides of the third semiconductor layers 1130 may be in contact with parts of a first reference voltage line 1360 of the first data conductive layer 1300. The third semiconductor layers 1130 may overlap with parts of a sensing signal line 1220 of the gate conductive layer 1200, which will be described later, between the first sides and the second sides thereof. Parts of the first data conductive layer 1300 that are in contact with the first sides of the third semiconductor layers 1130 may be the source electrodes of the second switching transistors SST, and parts of the first data conductive layer 1300 that are in contact with the second sides of the third semiconductor layers 1130 may be the drain electrodes of the second switching transistors SST. Parts of the gate conductive layer 1200 that overlap with the third semiconductor layers 1130, between the first sides and the second sides of the third semiconductor layers 1130, may be the gate electrodes of the second switching transistors SST.

In some embodiments, the semiconductor layer 1100 may include an oxide semiconductor. Examples of the oxide semiconductor of the semiconductor layer 1100 may include indium tin oxide (ITO), indium tin gallium oxide (ITGO), indium gallium zinc oxide (IGZO), or indium gallium zinc tin oxide (IGZTO), but the disclosure is not limited thereto.

The gate insulating film 1030 (see, e.g., FIG. 8) is disposed on the semiconductor layer 1100. This will be described later with reference to FIG. 8.

The gate conductive layer 1200 may be disposed on the gate insulating film 1030 or the buffer film 1020. The gate conductive layer 1200 may include the scan signal line 1210, the sensing signal line 1220, a plurality of gate conductive patterns 1250, and a gate pattern part 1260. The scan signal line 1210 may transmit a scan signal to the pixel PX or the first switching transistors SCT of the subpixels, and the sensing signal line 120 may transmit a sensing signal to the pixel PX or the second switching transistors SST of the subpixels. For example, the scan signal line 1210 may be the scan line SCL shown in FIG. 4, and the sensing signal line 1220 may be the sensing line SSL shown in FIG. 4. The gate conductive patterns 1250 may overlap with the first semiconductor layers 1110 to form the gate electrodes of the driving transistors DRT. The gate pattern part 1260 may be disposed to overlap with a second voltage line 1370 of the first data conductive layer 1300, which will be described later.

The scan signal line 1210 may extend in the first direction DR1 and may include a first extension 1215, which branches off of the scan signal line 1210 to extend in the second direction DR2. The scan signal line 1210 may extend in the first direction DR1 in the upper part of the pixel PX. The scan signal line 1210 may extend into neighboring pixels PX, in the first direction DR1, of the pixel PX. The first extension 1215 may be positioned in part of the scan signal line 1210, for example, on the right side of the center of the pixel PX, and may extend in the second direction DR2 to be disposed within the pixel PX.

The first extension 1215 of the scan signal line 1210 may overlap with parts of the second semiconductor layers 1120. The first extension 1215 may form the gate electrodes of the first switching transistors SCT in the pixel PX or the subpixels. The first switching transistors SCT may receive a scan signal input thereto from the scan signal line 1210 through the first extension 1215.

The sensing signal line 1220 may extend in the first direction DR1 and may include a second extension 1225, which branches off of the sensing signal line 1220 to extend in the second direction DR2. The sensing signal line 1220 may extend in the first direction DR1 in a lower part of the pixel PX. The sensing signal line 1220 may extend into the neighboring pixels PX, in the first direction DR1, of the pixel PX. The second extension 1225 may be positioned in part of the sensing signal line 1220, for example, on the left side of the center of the pixel PX, and may extend in the second direction DR2 to be disposed within the pixel PX.

The second extension 1225 of the sensing signal line 1220 may overlap with parts of the third semiconductor layer 1130. The second extension 1225 may form the gate electrodes of the second switching transistors SST in the pixel PX or the subpixels. The second switching transistors SST may receive a sensing signal input thereto from the sensing signal line 1220 through the second extension 1225.

The gate conductive patterns 1250 may be disposed between the first extension 1215 of the scan signal line 1210 and the second extension 1225 of the sensing signal line 1220. The gate conductive patterns 1250 may include a first gate conductive pattern 1250a, a second gate conductive pattern 1250b, and a third gate conductive pattern 1250c, and the first, second, and third gate conductive patterns 1250a, 1250b, and 1250c may partially overlap with the first semiconductor layers 1110. The first gate conductive pattern 1250a may overlap with part of the 11^{th} semiconductor layer 1110a to form the gate electrode of the driving transistor DRT of the first subpixel. The first gate conductive pattern 1250a may overlap, at least, with the channel region of the 11^{th} semiconductor layer 1110a. Similarly, the second gate conductive pattern 1250b may overlap with part of the 12^{th} semiconductor layer 1110b, and the third gate conductive pattern 1250c may overlap with part of the 13^{th} semiconductor layer 1110c. The second and third gate conductive patterns 1250b and 1250c may form the gate electrodes of the driving transistors DRT of the second and third subpixels.

The gate conductive patterns 1250 may also overlap with the first conductive patterns 1380 and the second conductive patterns 1390 of the first data conductive layer 1300. The gate conductive patterns 1250 may overlap with the first conductive patterns 1380 to form first electrodes of storage capacitors CST of the pixel PX or the subpixels. The gate conductive patterns 1250 may be in contact with the first conductive patterns 1380 to be electrically connected to the second switching transistors SST and may be in contact with the second conductive patterns 1390 to be electrically connected to the first switching transistors SCT.

For example, the first gate conductive pattern 1250a may overlap with an 11^{th} conductive pattern 1380a, which will be described later, to form the first electrode of a storage capacitor CST of the first subpixel. Also, the gate conductive pattern 1250 may be in contact with the 11^{th} conductive pattern 1380a to be electrically connected to the source electrode of the second switching transistor SST of the first subpixel and may be in contact with a 21^{st} conductive pattern 1390 to be electrically connected to the source electrode of the first switching transistor SCT of the first subpixel. Similarly, the second gate conductive pattern 1250b may partially overlap with, or may be partially in contact with, 12^{th} and 22^{nd} conductive patterns 1380b and 1390b, and the third gate conductive pattern 1250c may be partially in contact with 13^{th} and 23^{rd} conductive patterns 1380c and 1390c.

The gate pattern part 1260 may include an extension, which extends in the second direction DR2, and an expansion, which has a relatively large width in part. The gate pattern part 1260 may be disposed in a left part of the pixel PX and may be arranged between the scan signal line 1210 and the sensing signal line 1220, which extend in the first direction DR1. The gate pattern part 1260 may be electrically connected to the second voltage line 1370, which will be described later, and can lower the resistance of the second voltage line 1370.

The gate conductive layer 1200 may include at least one metal selected from among molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), Titanium (Ti), tantalum (Ta), tungsten (W), and copper (Cu). The gate conductive layer 1200 may be a single film or a multifilm.

A first interlayer insulating film 1050 (see, e.g., FIG. 8) is disposed on the gate conductive layer 1200. This will be described later with reference to FIG. 8.

The first data conductive layer 1300 is disposed on the first interlayer insulating film 1050. The first data conductive layer 1300 may include the first data signal lines (1310, 1320, and 1330), the first voltage line 1350, the second voltage line 1370, the first conductive patterns 1380, and the second conductive patterns 1390.

The first data signal lines (1310, 1320, and 1330) may transmit a data signal to the pixel or the subpixels. For example, the first data signal lines (1310, 1320, and 1330) may correspond to the data line DTL shown in FIG. 4. The first data signal lines (1310, 1320, and 1330) may be disposed on one side, in the first direction DR1, of the center of the pixel PX, for example, on the right side of the center of the pixel PX, and may extend in the second direction DR2. The first data signal lines (1310, 1320, and 1330) may extend into neighboring pixels PX, in the second direction DR2, of the pixel PX.

The first data signal lines (1310, 1320, and 1330) may include an 11^{th} data signal line 1310, a 12^{th} data signal line 1320, and a 13^{th} data signal line 1330. The 11^{th} data signal line 1310 may be in contact with a second side of the 21^{st} semiconductor layer 1120a to transmit a data signal to the first switching transistor SCT of the first subpixel. The 12^{th} data signal line 1320 may be in contact with a second side of the 22^{nd} semiconductor layer 1120b to transmit a data signal to the first switching transistor SCT of the second subpixel. The 13^{th} data signal line 1330 may be in contact with a second side of the 23^{rd} semiconductor layer 1120c to transmit a data signal to the first switching transistor STC of the third subpixel.

As will be described later with reference to FIG. 8, the first interlayer insulating film 1050, at where the first data conductive layer 1300 is disposed, may include a plurality of contact holes (e.g., contact openings). The contact holes may expose the semiconductor layer 1100 through the first interlayer insulating film 1050, the gate insulating film 1030, and/or the buffer film 1020.

The first interlayer insulating film 1050 may include a plurality of 37^{th} contact holes CNT37, which expose parts of the second semiconductor layers 1120 through the first interlayer insulating film 1050 and the gate insulating film 1030. The first data signal lines (1310, 1320, and 1330) may be in contact with the second sides of the second semiconductor layers 1120. For example, the 11^{th} data signal line 1310 may be in contact with the second side of the 21^{st} semiconductor layer 1120a through a (37-1)-th contact hole CNT37a. Similarly, the 12^{th} and 13^{th} data signal lines 1320 and 1330 may be in contact with the second sides of the 22^{nd} and 23^{rd} semiconductor layers 1120b and 1120c through (37-2)-th and (37-3)-th contact holes CNT37b and CNT37c.

The first voltage line 1350 may transmit the first power supply voltage ELVD to the pixel PX or the subpixels. For example, the first voltage line 1350 may be the first power supply line EVDL shown in FIG. 4. The first voltage line 1350 may be disposed on one side, in the first direction DR1, of the center of the pixel PX, for example, on the left side of the pixel PX, and may extend in the second direction DR2. The first voltage line 1350 may extend into the neighboring pixels PX, in the second direction DR2, of the pixel PX. The first voltage line 1350 may be in contact with the second sides of the first semiconductor layers 1110 to transmit the first power supply voltage ELVD to the driving transistors DRT of the subpixels.

The first interlayer insulating film 1050 may include a plurality of 35^{th} contact holes CNT35, which expose parts of the first semiconductor layers 1110. The first voltage line 1350 may be in contact with the second sides of the first semiconductor layers 1110 through the 35^{th} contact holes CNT35. For example, the first voltage line 1350 may be in contact with the second side of the 11^{th} semiconductor layer 1110a through a (35-1)-th contact hole CNT35a. Similarly, the first voltage line 1350 may be in contact with the second sides of the 12^{th} and 13^{th} semiconductor layers 1110b and 1110c through (35-1)-th and (35-3)-th contact holes CNT35b and CNT35c.

The first reference voltage line 1360 may transmit a reference voltage RV to the pixel PX or the subpixels. For example, the first reference voltage line 1360 may be the first power supply line ELVDL shown in FIG. 4. The first reference voltage line 1360 may be disposed on one side, in the first direction DR1, of the first voltage line 1350, for example, on the right side of the first voltage line 1350, and may extend in the second direction DR2. The first reference voltage line 1360 may extend into the neighboring pixels PX, in the second direction DR2, of the pixel PX. The first reference voltage line 1360 may be in contact with the second sides of the third semiconductor layers 1130 to transmit the reference voltage RV to the second switching transistors SST of the subpixels.

The first interlayer insulating film 1050 may include a plurality of 36^{th} contact holes CNT36, which expose parts of the first semiconductor layers 1110. The first voltage line 1350 may be in contact with the second sides of the first semiconductor layers 1110 through the 35^{th} contact holes CNT35. For example, the first voltage line 1350 may be in contact with the second side of the 11^{th} semiconductor layer 1110a through a (35-1)-th contact hole CNT35a. Similarly, the first voltage line 1350 may be in contact with the second sides of the 12^{th} and 13^{th} semiconductor layers 1110b and 1110c through (35-1)-th and (35-3)-th contact holes CNT35b and CNT35c.

The second voltage line 1370 may transmit the second power supply voltage ELVS to the pixel PX or the subpixels. For example, the second voltage line 1370 may be the second power supply line ELVSL shown in FIG. 4. The second voltage line 1370 may be disposed on one side, in the first direction DR1, of the first reference voltage line 1360, for example, on the left side of the first reference voltage line 1360, and may extend in the second direction DR2. The second voltage line 1370 may extend into the neighboring pixels PX, in the second direction DR2, of the pixel PX.

The second power supply voltage ELVS may be transmitted to a common electrode CMD, which is the first electrodes of light-emitting elements EMD, for example, the cathodes of the light-emitting elements EMD. The common electrode CMD may be connected to the second power supply lines ELVSL via a power line in the non-display area NDA and, thus, may receive the second power supply voltage ELVS.

However, when the display device 1 includes a considerable number of pixels PX and has a high resolution, a voltage drop may occur in the second power supply voltage ELVS, which is applied to the common electrode CME via the power supply line in the non-display area NDA, depending on the location in the display area DPA. Because the second power supply voltage ELVS that is applied to pixels PX distant from the non-display area NDA has a lower potential than the second power supply voltage ELVS applied to pixels PX near the non-display area NDA, the intensity of light emitted from light-emitting elements EMD of each pixel PX may not be uniform. Thus, in the display device 1, the second voltage line 1370, which is positioned in at least some pixels PX, and a fourth voltage line 1470, which will be described later, may be electrically connected to the common electrode CME. As a result, a second power supply voltage ELVS having a uniform potential can be applied to each pixel PX.

The common electrode CME may be in contact with some conductive layers in an opening area LDA (see, e.g., FIG. 5) of the pixel PX and, thus, may be electrically connected to the second and fourth voltage lines 1370 and 1470. In one embodiment, the second voltage line 1370 may include a first extension SP1, which extends in the second direction DR2, and a first expansion EP1, which is positioned in the opening area LDA and has a relatively large width. In the first expansion EP1, an opening hole HLD (see, e.g., FIG. 8) of the pixel-defining film PDL, which is positioned above the first data conductive layer 1300, may be located, and the common electrode CME may be in contact with other conductive layers through the opening hole HLD. The conductive layers may be in contact with the second and fourth voltage lines 1370 and 1470 through a contact hole in the planarization film 1080, and the common electrode CME may be electrically connected to the second and fourth voltage lines 1370 and 1470.

The second voltage line 1370 may also be in contact with the gate pattern part 1260 through 55^{th} and 57^{th} contact holes CNT55 and CNT57, which expose parts of the gate pattern part 1260 through the first interlayer insulating film 1050.

The first conductive patterns 1380 and the second conductive patterns 1390 may be disposed between the first data signal lines (1310, 1320, and 1330) and the first voltage line 1350. The first conductive patterns 1380 and the second conductive patterns 1390 may be disposed to overlap with the first sides of the first semiconductor layers 1110, the second semiconductor layers 1120, and the third semiconductor layers 1130, and the first conductive patterns 1380 may be disposed to overlap with the gate conductive patterns 1250. The first conductive patterns 1380 may be in contact with the first sides of the first semiconductor layers 1110 and the third semiconductor layers 1130 through a plurality of 31^{st} contact holes CNT31 and a plurality of 33^{rd} contact holes CNT33, which are formed in the first interlayer insulating film 1050. The second conductive patterns 1390 may be in contact with the first sides of the second semiconductor layers 1120 through a plurality of 32^{nd} contact holes CNT32, which are formed in the first interlayer insulating film 1050.

The first conductive patterns 1380 and the second conductive patterns 1390 may form the source electrodes of the driving transistors DRT of the subpixels and the source electrodes of the second switching transistors SST of the subpixels, and the second conductive patterns 1390 may form the source electrodes of the first switching transistors SCT of the subpixels. The first conductive patterns 1380 may overlap with the gate conductive patterns 1250 to form the second electrodes of the storage capacitors CST of the subpixels.

The first conductive patterns 1380 may include 11^{th} 12^{th} and 13^{th} conductive patterns 1380a, 1380b, and 1380c, and the second conductive patterns 1390 may include 21^{st}, 22^{nd}, and 23^{rd} conductive patterns 1390a, 1390b, and 1390c.

The 11^{th} conductive pattern 1380a may be in contact with a first side of the 11^{th} semiconductor layer 1110a through a (31-1)-th contact hole CNT31a, which exposes the first side of the 11^{th} semiconductor layer 1110a through the first interlayer insulating film 1050 and the gate insulating film 1030. The 11^{th} conductive pattern 1380a may form the source electrode of the driving transistor DRT of the first subpixel. Also, the 11^{th} conductive pattern 1380a may be in contact with a first side of the 31^{st} semiconductor layer 1130a through a (33-1)-th contact hole CNT33a, which exposes the first side of the 31^{st} semiconductor layer 1130a through the first interlayer insulating film 1050 and the gate insulating film 130. The 11^{th} conductive pattern 1380a may be electrically connected to the second switching transistor SST of the first subpixel.

The 21^{st} conductive pattern 1390a may be in contact with a first side of the 21^{st} semiconductor layer 1120a through a (32-1)-th contact hole CNT32a, which exposes the first side of the 21^{st} semiconductor layer 1120a through the first interlayer insulating film 1050 and the gate insulating film 1030. The 21^{st} conductive pattern 1390a may form the source electrode of the first switching transistor SCT of the first subpixel.

The first conductive patterns 1380 may be in contact with conductive layers, disposed on the first substrate 1010, through contact holes, exposing the conductive layers through the first interlayer insulating film 1050, the gate insulating film 1030, and the buffer film 1020. The 11^{th}, 12^{th}, and 13^{th} conductive patterns 1380a, 1380b, 1380c may be in contact with the conductive layers through 41^{st}, 42^{nd}, and 43^{rd} contact holes CNT41, CNT42, and CNT43, respectively.

In some embodiments, the display device 1 may further include a light-blocking layer BML (see, e.g., FIG. 8), which is disposed between the first substrate 1010 and the buffer film 1020. The first conductive patterns 1380 may be in contact with the light-blocking layer BML through the 41^{st} 42^{nd}, and 43^{rd} contact holes CNT41, CNT42, and CNT43. This will be described later with reference to FIG. 8.

The second conductive patterns 1390 may be in contact with the conductive layers through contact holes, exposing parts of the gate conductive patterns 1250 through the first interlayer insulating film 1050. The 21^{st} 22^{nd,} and 23^{rd} conductive patterns 1390a, 1390b, and 1390c may be in contact with the gate conductive patterns 1250 through 53^{rd} contact holes CNT53. The second conductive patterns 1390 may form the source electrodes of the first switching transistors SCT, and at the same time, connect the source electrodes of the first switching transistors SCT to the gate electrodes of the driving transistor DRT and the first electrodes of the storage capacitors CST.

The above descriptions of the 11^{th} and 21^{st} conductive patterns 1380a and 1390a may be directly applicable to the 12^{th} 13^{th} 22^{nd}, and 23^{rd} conductive patterns 1380b, 1380c, 1390b, and 1390c in the other subpixels.

The first data conductive layer 1300 may include at least one metal selected from among Mo, Al, Pt, Pd, Ag, Mg, Au, Ni, Nd, Ir, Cr, Ca, Ti, Ta, W, and Cu. The first data conductive layer 1300 may be a single film or a multifilm. For example, the first data conductive layer 1300 may be formed as a stacked structure, such as Ti/Al/Ti, Mo/Al/Mo, Mo/AlGe/Mo, or Ti/Cu.

The first passivation film 1060 (see, e.g., FIG. 8) is disposed on the first data conductive layer 1300. This will be described later with reference to FIG. 8.

The display device 1 may include the second data conductive layer 1400 in addition to the first data conductive layer 1300. The second data conductive layer 1400 may be disposed to overlap with the first data conductive layer 1300 and may have substantially the same shape as the first data conductive layer 1300. The first and second data conductive layers 1300 and 1400 may be electrically connected to each other. Lines transmitting power or data signals may be divided between different layers, for example, the first and second data conductive layers 1300 and 1400, thereby reducing or minimizing the space of the non-display area NDA where the wire pads WPD and wires or lines are disposed.

The second data conductive layer 1400, which corresponds to the first data conductive layer 1300, may include a plurality of second data signal lines (1410, 1420, and 1430), a third power supply line (e.g., a third voltage line) 1450, a second reference voltage line 1460, the fourth power supply line 1470, and a plurality of third conductive patterns 1480. The second data signal lines (1410, 1420, and 1430) may be disposed to overlap with the first data signal lines (1310, 1320, and 1330). The third power supply line 1450 may be disposed to overlap with the first voltage line 1350, the second reference voltage line 1460 may be disposed to overlap with the first reference voltage line 1360, and the fourth voltage line 1470 may be disposed to overlap with the second voltage line 1370. For example, the fourth voltage line 1470 may include a second extension SP2, which extends in one direction, and a second expansion EP2, which has a relatively large width. The layout and the shape of the second data conductive layer 1400 are substantially the same as the layout and the shape of the first data conductive layer 1300, described above, and thus, detailed descriptions thereof will be omitted.

The second data signal lines (1410, 1420, and 1430) may be in contact with the first data signal lines (1310, 1320, and 1330) through contact holes, exposing parts of the first data signal lines (1310, 1320, and 1330) through the first passivation film 1060. A 21^{st} data signal line 1410 may be in contact with the 11^{th} data signal line 1310 through a 21^{st} contact hole CNT21, a 22^{nd} data signal line 1420 may be in contact with the 12^{th} data signal line 1320 through a 22^{nd} contact hole CNT22, and a 23^{rd} data signal line 1430 may be in contact with the 13^{th} data signal line 1330 through a 23^{rd} contact hole CNT23.

The third voltage line 1450 may be in contact with the first voltage line 1350 through a 25^{th} contact hole CNT25, which exposes part of the first voltage line 1350. The second reference voltage line 1460 may be in contact with the first reference voltage line 1360 through a 26^{th} contact hole CNT26, and the fourth voltage line 1470 may be in contact with the second voltage line 1370 through a 27^{th} contact hole CNT27.

The third conductive patterns 1480 may be in contact with the first conductive patterns 1380 through 28^{th} contact holes CNT28, which expose parts of the first conductive patterns 1380 through the first passivation film 1060. A 31^{st} conductive pattern 1480a may be in contact with the 11^{th} conductive pattern 1380a through a (28-1)-th contact hole CNT28a. A 32^{nd} conductive pattern 1480b may be in contact with the 12^{th} conductive pattern 1380b through a (28-2)-th contact hole CNT28b, and a 33^{rd} conductive pattern 1480c may be in contact with the 13^{th} conductive pattern 1380c through a (28-3)-th contact hole CNT28c.

The second data conductive layer 1400 may include substantially the same material as the first data conductive layer 1300. A detailed description of the material of the second data conductive layer 1400 will be omitted.

The second passivation film 1070 (see, e.g., FIG. 8) and the planarization film 1080 (see, e.g., FIG. 8) are disposed on the second data conductive layer 1400. This will be described later with reference to FIG. 8.

A pixel electrode layer is disposed on the planarization film 1080. The pixel electrode layer includes pixel electrodes PXE, which are the anode electrodes of the light-emitting elements EMD of the subpixels, and an electrode pattern PXP, which is positioned in the opening area LDA. The opening area LDA may be an area where the electrode pattern PXP of the pixel PX is disposed.

The pixel electrodes PXE may include first, second, and third pixel electrodes PXE1, PXE2, and PXE3. The first pixel electrode PXE1 may be the anode electrode of the light-emitting element EMD of the first subpixel, the second pixel electrode PXE2 may be the anode electrode of the light-emitting element EMD of the second subpixel, and the third pixel electrode PXE3 may be the anode electrode of the light-emitting element EMD of the third subpixel.

The first pixel electrode PXE1 may be disposed on the right side of the center of the pixel PX. The first pixel electrode PXE1 may be disposed at a location overlapping with data signal lines (1310, 1320, 1330, 1410, 1420, and 1430) of the first and second data conductive layers 1300 and 1400. The first pixel electrode PXE1 may be in contact with the 31^{st} conductive pattern 1480a through a 11^{th} contact hole CNT11, which exposes the 31^{st} conductive pattern 1480a through the planarization film 1080. The first pixel electrode PXE1 may be electrically connected to the source electrode of the driving transistor DRT of the first subpixel through the 31^{st} conductive pattern 1480a.

The second pixel electrode PXE2 may be disposed around the center of the pixel PX. The second pixel electrode PXE2 may be disposed at a location overlapping with conductive patterns (1380 and 1480) of the first and second data conductive layers 1300 and 1400. The second pixel electrode PXE2 may be in contact with the 32^{nd} conductive pattern 1480b through a 12^{th} contact hole CNT12, which exposes the 32^{nd} conductive pattern 1480b through the first and second data conductive layers 1300 and 1400. The second pixel electrode PXE2 may be electrically connected to the source electrode of the driving transistor DRT of the second subpixel through the 32^{nd} conductive pattern 1480b.

The third pixel electrode PXE3 may be disposed on the left side of the center of the pixel PX. The third pixel electrode PXE3 may be disposed at a location overlapping with the first voltage line 1350, the third voltage line 1450, and the reference voltage lines 1360 and 1460 of the first and second data conductive layers 1300 and 1400. The third pixel electrode PXE3 may be in contact with the 33^{rd} conductive pattern 1480c through a 13^{th} contact hole CNT13. The third pixel electrode PXE3 may be electrically connected to the source electrode of the driving transistor DRT of the third subpixel through the 33^{rd} conductive pattern 1480c.

The display device 1 may include the electrode pattern PXP, which is disposed in the pixel electrode layer. In one embodiment, the electrode pattern PXP, which is disposed in the same layer as the pixel electrodes PXE, may be disposed to overlap with the second and fourth voltage lines 1370 and 1470, to which the second power supply voltage ELVS is applied. For example, the electrode pattern PXP may be disposed in the opening area LDA of the pixel PX and may at least partially overlap with the first and second expansions EP1 and EP2 of the second and fourth voltage lines 1370 and 1470 in a thickness direction. The electrode pattern PXP may include a third expansion EP3 and a protrusion PP. As will be described later, the third expansion EP3 may be in contact with the common electrode CME, and the protrusion PP may be in contact with the data conductive layers 1300 and 1400 disposed therebelow. This will be described later with other drawings.

The pixel-defining film PDL may be disposed on the pixel electrode layer and the planarization film 1080. The pixel-defining film PDL may have a plurality of openings OPH and may also have an opening hole HLD in the pixel PX. The locations of the openings OPH and the opening hole HLD are as illustrated in the drawings. The pixel-defining film PDL is as the same as described above with reference to FIG. 2.

The openings OPH may expose parts of the pixel electrodes PXE. The openings OPH may include first, second, and third openings OPH1, OPH2, and OPH3 and may expose parts of the pixel electrodes PXE. The first opening OPH1 may be positioned on the first pixel electrode PXE1 to expose part of the first pixel electrode PXE1. The second opening OPH2 may be positioned on the second pixel electrode PXE2 to expose part of the second pixel electrode PXE2, and the third opening OPH3 may be positioned on the third pixel electrode PXE3 to expose part of the third pixel electrode PXE3. As already mentioned above, the emission layer EML and the common electrode CME may be disposed in the entire pixel PX, on the pixel-defining film PDL and the pixel electrode PXE. The emission layer EML may be in contact with parts of the pixel electrodes PXE, exposed by the openings OPH, and may receive electric signals from the pixel electrodes PXE and the common electrode CME to emit light.

However, the emission layer EML may not be disposed in the opening hole HLD of the opening area LDA. The opening hole HLD may be disposed at a location overlapping the electrode pattern PXP and may expose part of the electrode pattern PXP through the pixel-defining film PDL. During the fabrication of the display device 1, the opening hole HLD is formed after the arrangement of the emission layer EML on the entire surface of the pixel PX, the emission layer EML may not be disposed on part of the electrode pattern PXP, exposed by the opening hole HLD. Accordingly, the common electrode CME, which is disposed on the entire surface of the pixel PX, on the emission layer EML, may be in contact with the electrode pattern PXP through the opening hole HLD.

Electrode pads 1500 may be disposed in contact holes where the pixel electrode layer is in contact with the second data conductive layer 1400, for example, a 15^{th} contact hole CNT15, in which the electrode pattern PXP and the fourth voltage line 1470 are in contact with each other, and the 11^{th,} 12^{th} and 13^{th} contact holes CNT11, CNT12, and CNT13, in which the pixel electrodes PXE are in contact with the third conductive patterns 1480. The electrode pads 1500 may be provided to lower the contact resistance between the pixel electrode layer and the second data conductive layer 1400, in a region where the pixel electrode layer and the second data conductive layer 1400 are in contact with each other, but the disclosure is not limited thereto. In some embodiments, the electrode pads 1500 may be omitted.

A cross section of part of the pixel PX of the display device 1 will hereinafter be described with other drawings.

FIG. 8 is a cross-sectional view taken along the lines IXa-IXa′ and IXb-IXb′ of FIG. 5.

FIG. 8 illustrates a cross section of part of the pixel PX of the display device 1, including the driving transistor DRT, the storage capacitor CST, and the first pixel electrode PXE1 of the first subpixel. FIG. 8 illustrates the stack structure of a circuit layer CCL and also illustrates the pixel-defining film PDL, the emission layer EML, and the common electrode CME. The following description with reference to FIG. 8 may be directly applicable to the other subpixels of the pixel PX.

Referring to FIG. 8, the driving transistor DRT may include a first active layer 350, a first gate electrode 310, a first source electrode 330, a first drain electrode 340, and the light-blocking layer BML. The first active layer 350, the first gate electrode 310, the first source electrode 330, and the first drain electrode 340 of the driving transistor DRT may correspond to some of the first semiconductor layers 1110, the gate conductive patterns 1250, the first conductive patterns 1380, and the first voltage line 1350. For example, FIG. 8 illustrates that parts of semiconductor layers and parts of conductive layers form a single driving transistor DRT, and it may be understood that for convenience, the parts of the semiconductor layers and the parts of the conductive layers are referred to by new reference numerals.

The first substrate 1010 may be an insulating substrate. The first substrate 1010 may include a transparent material. The first substrate 1010 is already described above.

The buffer film 1020 is disposed on the first substrate 1010. The buffer film 1020 may protect the driving transistor DRT, the first switching transistor SCT, and the second switching transistor SST from moisture that may penetrate through the first substrate 1010. The buffer film 1020 may include a plurality of inorganic layers that are alternately stacked. For example, the buffer film 1020 may be formed as a multilayer in which at least one inorganic layer from among a silicon oxide (SiOₓ) layer, a silicon nitride (SiNₓ) layer, and a silicon oxynitride (SiON) layer is stacked.

In some embodiments, the light-blocking layer BML may be further disposed between the first substrate 1010 and the buffer film 1020 of the display device 1. The light-blocking layer BML may be disposed to overlap with the first active layer 350 of the driving transistor DRT. The light-blocking layer BML may block light from being incident upon the first active layer 350 of the driving transistor DRT from the first substrate 1010 and may thereby prevent a leakage current that may flow in the first active layer 350. The width of the light-blocking layer BML may be greater than the width of the first active layer 350 of the driving transistor DRT. The light-blocking layer BML may be disposed to cover a channel region of the first active layer 350, but the disclosure is not limited thereto.

As illustrated in FIG. 8, the light-blocking layer BML may be in contact with the first source electrode 330 through the 41^{st} contact hole CNT41, which exposes part of the light-blocking layer BML. As a result, the light-blocking layer BML can suppress a variation in the voltage of the driving transistor DRT. Also, the light-blocking layer BML may be disposed to overlap with gate conductive patterns 1250. Accordingly, a storage capacitor may be formed between the light-blocking layer BML and the gate conductive patterns 1250. The light-blocking layer BML may be formed as a Ti/Cu double film in which a Ti layer and a Cu layer are stacked, but the disclosure is not limited thereto.

The first active layer 350 or the first semiconductor layers 1110 are disposed on the buffer film 1020. FIG. 8 illustrates only the first active layer 350 of the driving transistor DRT, but the active layers of the first and second switching transistors SCT and SST may also be disposed on the buffer film 1020. The first active layer 350 may include a first conductive region 350a, a second conductive region 350b, and a channel region 350c. The first source electrode 330 may be in contact with the first conductive region 350a, and the first drain electrode 340 may be in contact with the second conductive region 350b.

As already mentioned above, the first active layer 350 may include an oxide semiconductor, but the disclosure is not limited thereto. In some embodiments, some of the semiconductor layers disposed on the buffer film 1020 may include polysilicon.

The gate insulating film 1030 is disposed on the first active layer 350. The gate insulating film 1030 may be formed of an inorganic material, such as, for example, SiOₓ, SiNₓ, or a stack of both. The gate insulating film 1030 is illustrated as being disposed not only on the first active layer 350 but also on the entire surface of the buffer film 1020, but the disclosure is not limited thereto. In some embodiments, the gate insulating film 1030 may be formed only on the first active layer 350.

The first gate electrode 310 of the driving transistor DRT and the first electrode of the storage capacitor CST may be disposed on the gate insulating film 1030. The first gate electrode 310 and the first electrode of the storage capacitor CST may correspond to the gate conductive patterns 1250 of FIGS. 5 through 7. The gate conductive patterns 1250 may overlap with the light-blocking layer BML and a first conductive pattern 1380 that will be described later, in the thickness direction. The gate conductive patterns 1250 may correspond to the first electrode of the storage capacitor CST, and the light-blocking layer BML and the first conductive pattern 1380 may correspond the second electrode of the storage capacitor CST. The storage capacitor CST may have a relatively large capacitance.

The first gate electrode 310 may overlap with the first active layer 350 with the gate insulating film 1030 interposed therebetween. For example, the first gate electrode 310 may overlap with the channel region 350c of the first active layer 350.

The interlayer insulating film 1050 is disposed on the first gate electrode 310 and the first electrode of the storage capacitor CST. The interlayer insulating film 1050 may be formed of an inorganic material, such as, for example, SiOₓ, SiNₓ, or a stack of both.

31^{st} and 35^{th} contact holes CNT31 and CNT35 may be formed in the interlayer insulating film 1050. The 31^{st} contact hole CNT31 may be formed to expose the first conductive region 350a of the first active layer 350, and the 35^{th} contact hole CNT35 may be formed to expose the second conductive region 350b of the first active layer 350. A contact hole (e.g., the 41^{st} contact hole CNT41) exposing part of the light-blocking layer BML may be formed in the interlayer insulating film 1050. As already mentioned above, various other contact holes may also be formed in the interlayer insulating film 1050.

The first data conductive layer 1300 is disposed on the interlayer insulating film 1050. The first conductive pattern 1380 of the first data conductive layer 1300 may be in contact with the first conductive region 350a of the first active layer 350 through the 31^{st} contact hole CNT31. The first conductive pattern 1380 may form the first source electrode 330 of the driving transistor DRT. Also, the first conductive pattern 1380 may overlap with the gate conductive patterns 1250 and may form the second electrode of the storage capacitor CST. The first voltage line 1350 of the first data conductive layer 1300 may be in contact with the second conductive region 350b of the first active layer 350 through the 35^{th} contact hole CNT35. The first voltage line 1350 may form the first drain electrode 340 of the driving transistor DRT.

The first passivation film 1060 is disposed on the first data conductive layer 1300. The first passivation film 1060 is disposed on the first data conductive layer 1300 or on the first source electrode 330 and the first drain electrode 340 of the driving transistor DRT. The first passivation film 1060 may be formed of an inorganic material, such as, for example, SiOₓ, SiNₓ, or a stack of both. A 25^{th} contact hole CNT25, which exposes the first voltage line 1350 through the first passivation film 1060, may be formed in the first passivation film 1060. A 28^{th} contact hole CNT28, which exposes part of the first conductive pattern 1380, may also be formed in the first passivation film 1060.

The second data conductive layer 1400 is disposed on the first passivation film 1060. The third voltage line 1450 of the second data conductive layer 1400 may be in contact with the first voltage line 1350 through the 25^{th} contact hole CNT25. A third conductive pattern 1480 may be in contact with the first conductive pattern 1380 through the 28^{th} contact hole CNT28.

The second passivation film 1070 is disposed on the second data conductive layer 1400. The second passivation film 1070 may be formed of an inorganic material, such as, for example, SiOₓ, SiNₓ, or a stack of both.

The planarization film 1080 is disposed on the second passivation film 1070. The planarization film 1080 may planarize height differences formed by thin-film transistors, such as the driving transistor DRT and the first switching transistor SCT.

The pixel electrodes PXE and the electrode pattern PXP of the pixel electrode layer may be disposed on the planarization film 1080. FIG. 8 illustrates parts of the first and third pixel electrodes PXE1 and PXE3. The first pixel electrode PXE1 may be in contact with the third conductive pattern 1480 through the 11^{th} contact hole CNT11.

The display device 1 may further include the electrode pads 1500, and electrode contact holes CNTI, which expose parts of the second data conductive layer 1400, may be formed in the second passivation film 1070. The electrode contact holes CNTI may be formed in regions where the pixel electrodes PXE are in contact with the second data conductive layer 1400, and the electrode pads 1500 may be disposed on parts of the second data conductive layer 1400, exposed by the electrode contact holes CNTI. As illustrated in FIG. 8, a first electrode contact hole CNTI1, which exposes part of the third conductive pattern 1480, may be formed in the second passivation film 1070, and a first electrode pad 1510 may be disposed on the second passivation film 1070 and the third conductive pattern 1480. The first pixel electrode PXE1 may be in contact with the third conductive pattern 1480 through the first electrode pad 1510. As a result, the contact resistance between the first pixel electrode PXE1 and the third conductive pattern 1480 can be lowered.

The pixel-defining film PDL is disposed on the planarization film 1080. FIG. 8 illustrates part of the third opening OPH3, which is formed in the pixel-defining film PDL. The emission layer EML, which is disposed on the pixel-defining film PDL, may be in contact with part of the third pixel electrode PXE3, exposed by the third opening OPH3. The common electrode CME is disposed on the emission layer EML, as already mentioned above.

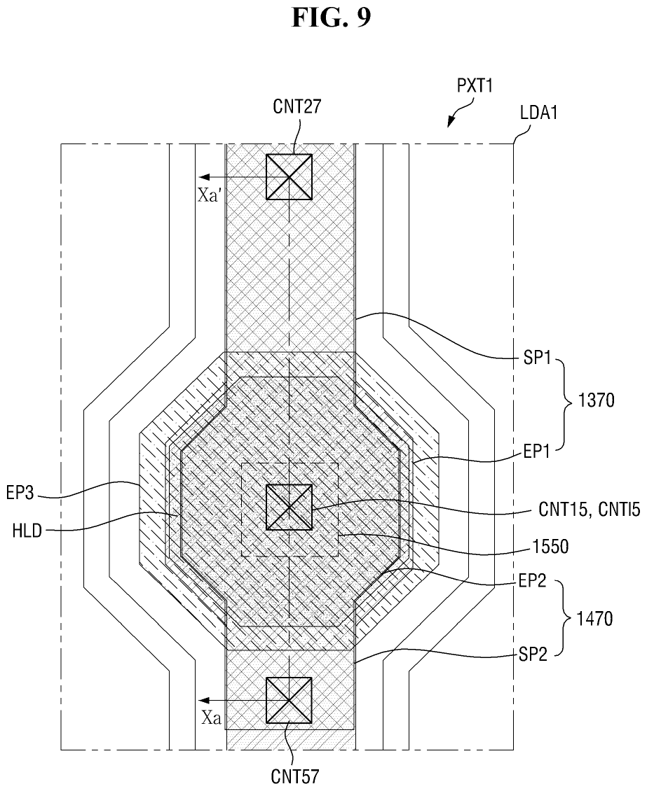

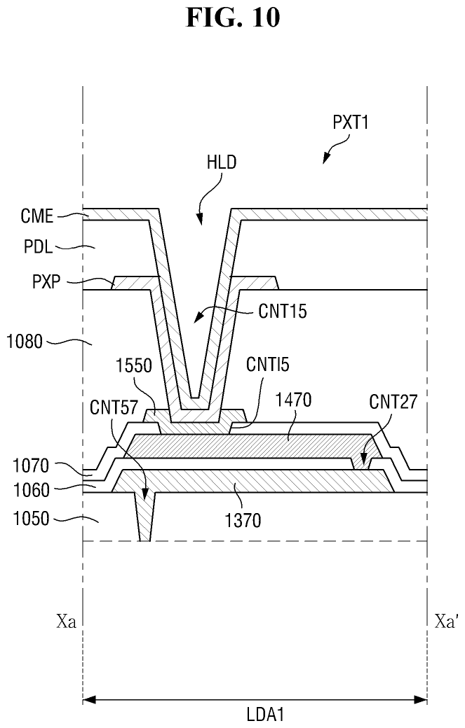

FIG. 9 is an enlarged view of an opening area of FIG. 5, and FIG. 10 is a cross-sectional view taken along the line Xa-Xa′ of FIG. 9.

FIGS. 9 and 10 illustrate a plan view and a cross-sectional view of the opening area LDA of the pixel PX shown in FIG. 5. FIG. 10 illustrates a cross-sectional view, taken along the line X-X′ of FIG. 9, of the electrode pattern PXP.

Referring to FIGS. 9 and 10, in the opening area LDA of the pixel PX, the electrode pattern PXP may be disposed. The electrode pattern PXP may be in contact with the gate conductive layer 1200, the first data conductive layer 1300, and the second data conductive layer 1400, which are disposed below the electrode pattern PXP. In the opening area LDA, the gate pattern part 1260, the second voltage line 1370, and the fourth voltage line 1470 are disposed. Also, in the overlapping area of the fourth voltage line 1470 and the electrode pattern PXP, a second electrode pad 1550 may be further disposed, or may, in some embodiments, be omitted. The pixel-defining film PDL may be disposed on the entire electrode pattern PCP except for in the opening hole HLD, and the common electrode CME is disposed on the electrode pattern PXP. In the opening area LDA, the emission layer EML may not be disposed on the pixel-defining film PDL, and the common electrode CME may be disposed directly on the pixel-defining film PDL. In the pixel PX of the display device 1, the opening hole HLD may be formed in the opening area LDA, and in the pixel PX, including the opening hole HLD, the common electrode CME may be in contact with the electrode pattern PXP.

Each of the second voltage line 1370, the fourth voltage line 1470, and the electrode pattern PXP may include an expansion EP. The second voltage line 1370 may include the first extension SP1 and the first expansion EP1, which has a larger width than the first extension SP1, and the fourth voltage line 1470 may include the second extension SP2 and the second expansion EP2. The first and second expansions EP1 and EP2 may be disposed to overlap with each other in the thickness direction. The first and second extensions SP1 and SP2 may be in contact with each other through the 27^{th} contact hole CNT27. The gate pattern part 1260 may also include an expansion and an extension, and the second voltage line 1370 may be in contact with the gate pattern part 1260 through the 57^{th} contact hole CNT57. As the gate pattern part 1260, the second voltage line 1370, and the fourth voltage line 1470 are electrically connected to one another, the second and fourth voltage lines 1370 and 1470 may have the same potential in response to the second power supply voltage ELVS being applied to the second and fourth voltage lines 1370 and 1470.

The electrode pattern PXP may include the third expansion EP3. The third expansion EP3 may be disposed to overlap with the first and second expansions EP1 and EP2. The opening hole HLD, which is formed in the pixel-defining film PDL, may be disposed above the third expansion EP3 of the electrode pattern PXP.

The width of the third expansion EP3 of the electrode pattern PXP may be greater than the width of the opening hole HLD. Part of the electrode pattern PXP may be disposed below the pixel-defining film PDL, and only part of the electrode pattern PXP may be exposed through the opening hole HLD. The common electrode CME may be in contact with the exposed part of the electrode pattern PXP through the opening hole HLD. The electrode pattern PXP may be in contact with the fourth voltage line 1470 or the second electrode pad 1550 through the 15^{th} contact hole CNT15 and/or a second electrode contact hole CNTIS. Accordingly, the common electrode CME can suppress a voltage drop by being in contact with the electrode pattern PXP, which has the same potential as the fourth voltage line 1470 within the pixel PX, through the opening hole HLD.

Also, in one embodiment, the display device 1 may include contact holes having different widths. For example, the 11^{th} contact hole CNT11, through which the first pixel electrode PXE1 is in contact with the 31^{st} conductive pattern 1480a, may have a different width than the 15^{th} contact hole CNT15, through which the electrode pattern PXP is in contact with the fourth voltage line 1470. Also, the 28^{th} contact hole CNT28, through which the third conductive pattern 1480 is in contact with the first conductive pattern 1380, may have a different width from the 11^{th} and 15^{th} contact holes CNT11 and CNT15. As these contact holes are formed to connect different members, for example, the first pixel electrode PXE1, the electrode pattern PX, the third conductive pattern 1480, the fourth voltage line 1470, and the first conductive pattern 1380, they may have different widths depending on the locations of the first pixel electrode PXE1, the electrode pattern PX, the third conductive pattern 1480, the fourth voltage line 1470, and the first conductive pattern 1380 or the order in which the first pixel electrode PXE1, the electrode pattern PX, the third conductive pattern 1480, the fourth voltage line 1470, and the first conductive pattern 1380 are stacked. However, the disclosure is not limited to this.

In one embodiment, the opening hole HLD may be formed in the pixel PX, but not in other neighboring pixels PX. The electrode pattern PXP may be disposed in the opening area LDA of each pixel PX. For example, the opening hole HLD is formed in only some pixels PX, for example, in the pixel PX of FIG. 5, so that the common electrode CME is in contact with the electrode pattern PXP, but the opening hole HLD may not be formed in other pixels PX. The opening hole HLD may not be formed in some of pixels PX disposed in an outermost part of the display area DPA, and the second power supply lines ELVDS, which are disposed in the non-display area NDA, may be electrically connected to the common electrode CME.

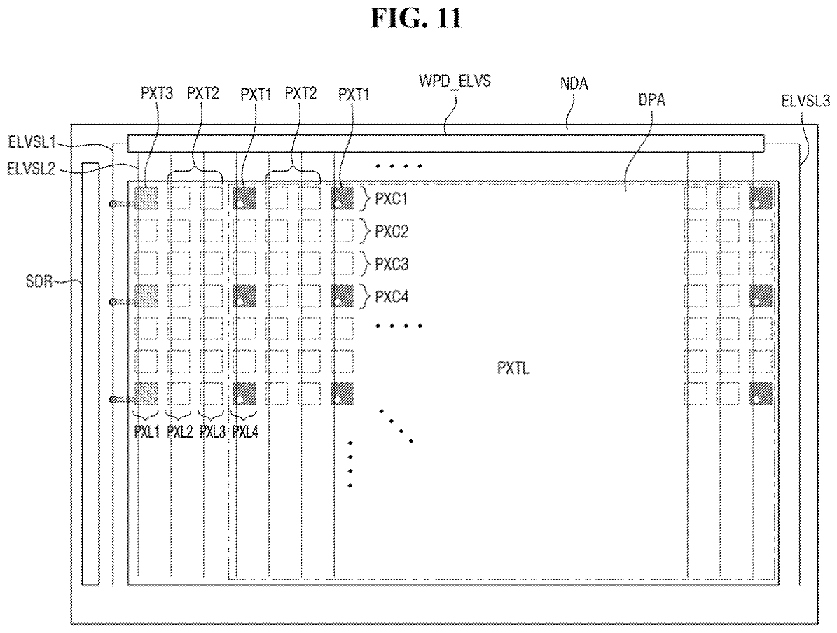

FIG. 11 is a plan view illustrating the layout of pixels in the display device according to an embodiment of the disclosure.

Referring to FIG. 11, the display device 1 may include, from among a plurality of pixels PX, first-type pixels PXT1, which include opening holes HLD, and second-type pixels PXT2 and third-type pixels PXT3, which do not include opening holes HLD. In the second-type pixels PXT2 and the third-type pixels PXT3, opening holes HLD are not formed, and the common electrode CME is not in contact with electrode patterns PXP. However, in the third-type pixels PXT3, opening holes HLD are not formed, and the common electrode CME may be either in contact with, or electrically connected to, the second power supply lines ELVSL in the non-display area NDA.

As described above, a plurality of pixels PX are disposed in the display area DPA of the display device 1, and the wire pads WPD and the scan driver SDR may be disposed in the non-display area NDA of the display device 1. FIG. 11 illustrates that the scan driver SDR is disposed in a non-display area NDA on one side of the display area DPA, for example, on the left side of the display area DPA, and the second power supply pad WPD_ELVS is disposed in a non-display area NDA on the upper side of the display are DPA, but the disclosure is not limited thereto. For example, the locations of the scan driver SDR and the second power supply pad WPD_ELVS may vary. Also, as illustrated in FIG. 11, a single second power supply pad WPD_ELVS may be provided to cover the entire display area DPA, but the disclosure is not limited thereto. In other embodiments, multiple second power supply pads WPD_ELVS may be provided and may each cover only part of the display area DPA.

The second power supply lines ELVSL may be connected to the second power supply pad WPD_ELVS, on one side thereof, and may extend in one direction to be disposed in the display area DPA and the non-display area NDA, on the other side thereof. The second power supply lines ELVSL may include a 21^{st} power supply line, 22^{nd} power supply lines ELVSL2, and a 23^{rd} power supply line ELVSL3, and the 21^{st} power supply line, the 22^{nd} power supply lines ELVSL2, and the 23^{rd} power supply line ELVSL3 may extend in one direction. The 21^{st} power supply line ELVSL1 may extend in one direction on one side of the display area DPA, for example, in the non-display area NDA on the left side of the display area DPA, and a plurality of 22^{nd} power supply lines ELVSL2 may extend in one direction across multiple pixels PX in the display area DPA. The 23^{rd} power supply line ELVSL3 may extend in one direction on the other side of the display area DPA, for example, in a non-display area NDA on the right side of the display area DPA. The second power supply lines ELVSL may receive the same second power supply voltage ELVS.

As already mentioned above, each of the pixels PX may include an electrode pattern PXP, and the electrode pattern PXP may be in contact with a second voltage line 1370 and/or a fourth voltage line 1470 and, thus, may have the same potential as the 22^{nd} power supply line ELVSL2. However, from among the pixels PX of the display device 1, only the first-type pixels PXT1 may include opening holes HLD so that electrode patterns PXP of the first-type pixels PXT1 may be in contact with the common electrode CME. For example, the pixel PX described above with reference to FIGS. 9 and 10 may be a first-type pixel PXT1 shown in FIG. 11. The first-type pixels PXT1 may be pixels PX where the formation of opening holes HLD is performed by applying laser light to parts of first opening areas LDA1.

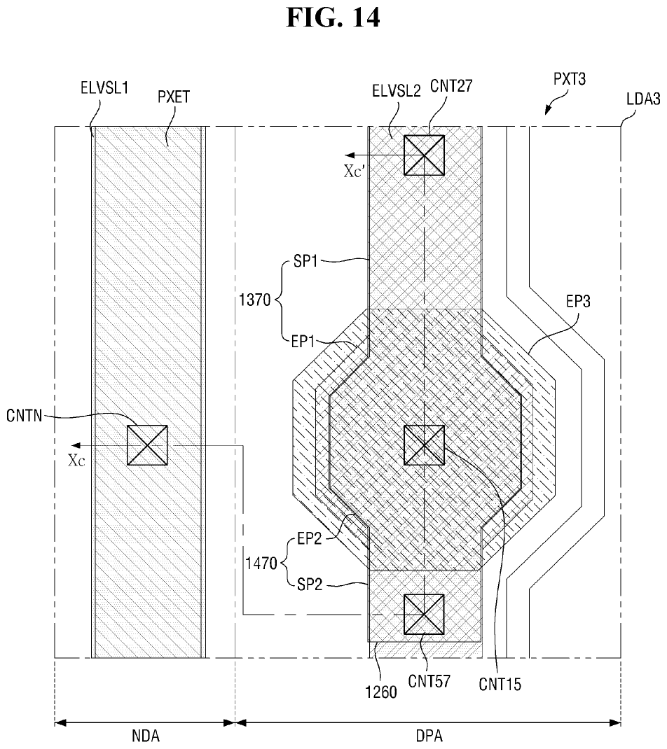

The display device 1 may further include second-type pixels PXT2 and third-type pixels PXT3, in which openings holes HLD are not formed, and the third-type pixels PXT3 may be disposed in an outer part of the display area DPA so that the second power supply lines ELVSL in the non-display area NDA and the common electrode CME may be electrically connected. In the third-type pixels PXT3, unlike in the first-type pixels PXT1, opening holes HLD may not be formed, but the common electrode CME may be in contact with sub-electrode patterns PXET (see, e.g., FIG. 14) having the same potential as the second power supply lines ELVSL, in the non-display area NDA. For example, the display area DPA may include first-type pixels PXT1 and third-type pixels PXT3, in which the common electrode CME is electrically connected to the second power supply lines ELVSL.

The pixels PX may be arranged in the display area DPA to form multiple pixel rows PXC and multiple pixel columns PXL. For example, the pixels PX may include, as the multiple pixel rows PXC, first, second, third, and fourth pixel rows PXC1, PXC2, PXC3, and PXC4 and, as the multiple pixel columns PXL, first, second, third, and fourth pixel columns PXL1, PXL2, PXL3, and PXL4.

The first-type pixels PXT1 and the third-type pixels PXT3 may be disposed to be spaced apart from one another, and the second-type pixels PXT2 may be disposed between the first-type pixels PXT1 and the third-type pixels PXT3.

In the first and fourth pixel rows PXC1 and PXC4, the first-type pixels PXT1 may be arranged in the fourth pixel column PXL4 and other pixel columns PXL subsequent to the fourth pixel column PXL4 and may be spaced apart from one another. In the first pixel column PXL1, the third-type pixels PXT3 may be arranged in the first pixel row PXC1, the fourth pixel row PXC4, and other pixel rows PXC subsequent to the fourth pixel row PXC4 and may be spaced apart from one another. Two arbitrary first-type pixels PXT1 may be disposed to be spaced apart from each other, and second-type pixels PXT2 may be disposed between the two arbitrary first-type pixels PXT1. Also, two arbitrary third-type pixels PXT3 may be disposed to be spaced apart from each other, and second-type pixels PXT2 may be disposed between the two arbitrary third-type pixels PXT3. Also, one arbitrary first-type pixel PXT1 and one arbitrary third-type pixel PXT3 may be disposed to be spaced apart from each other, and second-type pixels PXT2 may be disposed between the arbitrary first-type pixel PXT1 and the arbitrary third-type pixel PXT3.

FIG. 11 illustrates that two second-type pixels PXT are provided between a pair of adjacent first-type pixels PXT1, between a pair of adjacent third-type pixels PXT3, and between a pair of adjacent first- and third-type pixels PXT1 and PXT3, but the disclosure is not limited thereto. In some embodiments, more than two second-type pixels PXT2 may be provided between a pair of adjacent first-type pixels PXT1, between a pair of adjacent third-type pixels PXT3, and between a pair of adjacent first-and third-type pixels PXT1 and PXT3. For example, the distances between the first-type pixels PXT1, between the third-type pixels PXT3, and between the first-type pixels PXT1 and the third-type pixels PXT3 may vary. In some embodiments, there may exist a region where the distances between the first-type pixels PXT1, between the third-type pixels PXT3, and between the first-type pixels PXT1 and the third-type pixels PXT3 vary, and this will be described later.

During the fabrication of the display device 1, opening holes HLD may be formed by forming an emission layer EML on a pixel-defining film PDL and etching away parts of opening areas LDA with laser light. In one embodiment, the opening holes HLD may be formed only in some pixels (e.g., in the first-type pixels PXT1), rather than in all the pixels PX in the display area DPA, in consideration of the life of laser irradiation equipment. The opening holes HLD may not be formed in pixels in the outermost part of the display area DPA, for example, in the third-type pixels PXT3, and in the non-display area NDA, where the common electrode CME may be connected to the second power supply lines ELVSL. In this manner, a voltage drop in the second power supply voltage ELVS, which is applied to the common electrode CME in each of the pixels PX of the display area DPA, can be suppressed, and the number of laser irradiation processes for forming the opening holes HLD can be reduced.

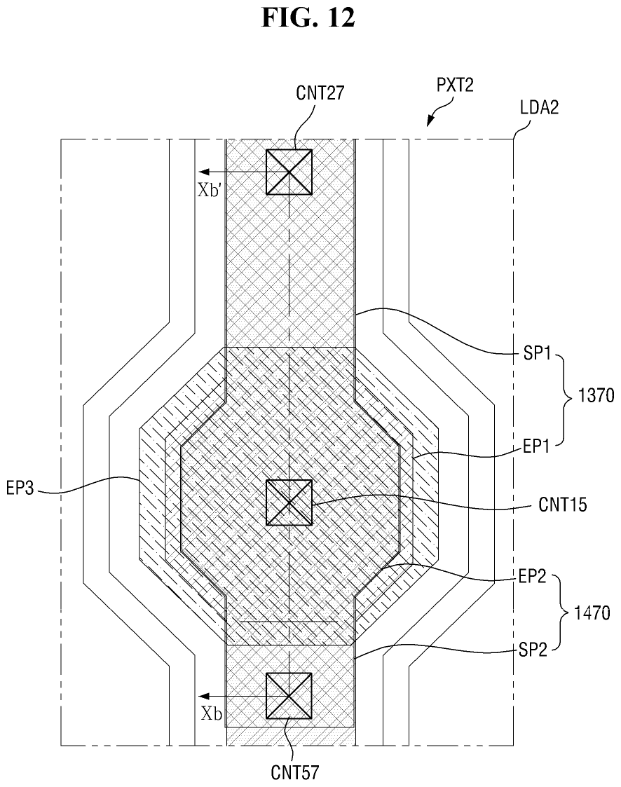

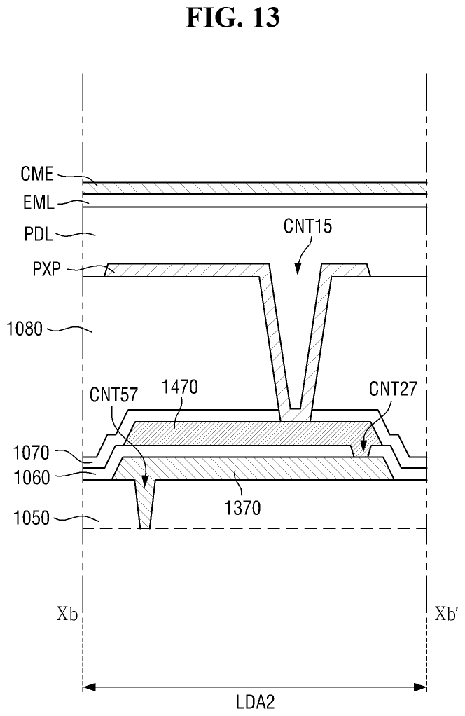

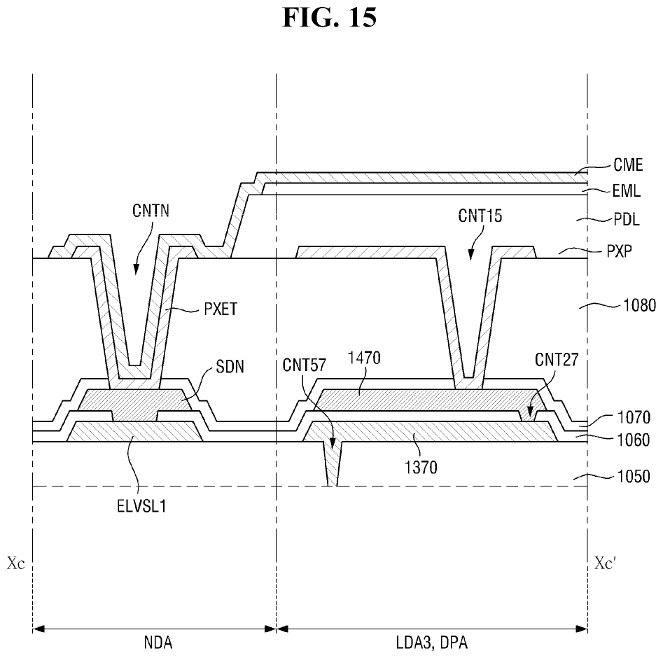

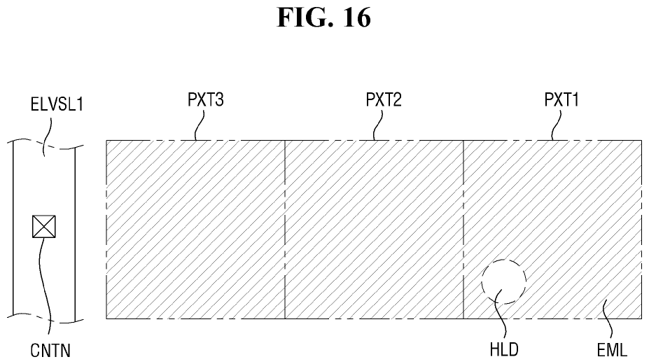

FIG. 12 is an enlarged view of an opening area of a second-type pixel of the display device according to an embodiment of the disclosure. FIG. 13 is a cross-sectional view taken along the line Xb-Xb′ of FIG. 12. FIG. 14 is an enlarged view of an opening area of a third-type pixel and part of a non-display area of the display device according to an embodiment of the disclosure. FIG. 15 is a cross-sectional view taken along the line Xc-Xc′ of FIG. 14. FIG. 16 is a schematic view illustrating the layout of pixels in the display device according to an embodiment of the disclosure.

FIGS. 12 and 13 illustrate a plan view and a cross-sectional view of an opening area LDA of a second-type pixel PXT2, and FIGS. 14 and 15 illustrate a plan view and a cross-sectional view of an opening area LDA of a third-type pixel PXT3 and part of the non-display area NDA. FIG. 16 illustrates the shapes of emission layers EML disposed in different types of pixels.

Referring to FIGS. 12 through 16, a second-type pixel PXT2 differs from a first-type pixel PXT1 in that an opening hole HLD is not formed and that a common electrode CME is not in contact with an electrode pattern PXP. In a second opening area LDA2 of the second-type pixel PXT2, an opening hole HLD may not be formed in a region where a third expansion EP3 of the electrode pattern PXP is disposed, and the electrode pattern PXP may not be exposed. A pixel-defining film PDL may be disposed to cover the electrode pattern PXP, and an emission layer EML may be disposed on the pixel-defining film PDL, on the electrode pattern PXP.

A third-type pixel PXT3 may not have an opening hole HLD in an opening area LDA thereof. In a third opening area LDA3 of the third-type pixel PXT3 may have substantially the same cross-section as the second opening area LDA2 of the second-type pixel PXT2. As illustrated in FIG. 16, the first-type pixel PXT1 may include an opening hole HLD, and an emission layer EML may be disposed in the entire first-type pixel PXT1 except for the opening hole HLD. In each of the second-and third-type pixels PXT2 and PXT3, an opening hole HLD may not be formed, and an emission layer EML may be disposed on the entire surface of a pixel-defining film PDL.

The third-type pixel PXT3 may be disposed in the outermost part of the display area DPA, adjacent to the 21^{st} power supply line ELVSL1, which is disposed in the non-display area NDA. In the non-display area NDA, a data pattern SDN and a sub-electrode pattern PXET may be further disposed to overlap with the 21^{st} power supply line ELVSL1. The data pattern SDN may be disposed in the second data conductive layer 1400 and may be in contact with the 21^{st} power supply line ELVSL1, but the disclosure is not limited thereto. In some embodiments, the data pattern SDN may be omitted.

The sub-electrode pattern PXET may be in contact with the 21^{st} power supply line ELVSL1 or the data pattern SDN through a power supply contact hole CNTN, which exposes the 21^{st} power supply line ELVSL1 or the data pattern SDN through the planarization film 1080. The sub-electrode pattern PXET may have the same potential as the 21^{st} power supply line ELVSL1. The third-type pixel PXT3 may be disposed around a region where the common electrode CME is in contact with the sub-electrode pattern PXET in the non-display area NDA. The third-type pixel PXT3 may be understood as having the common electrode CME partially in contact with the sub-electrode pattern PXET.

As already mentioned above, in a high-resolution display device 1, the common electrode CME may be placed in contact with patterns having the same potential as the second power supply lines ELVSL, in some pixels PX, to suppress a drop in the second power supply voltage ELVS, which is applied to the common electrode CME. The display device 1 may include first-type pixels PXT1, in which the common electrode CME is in contact with electrode patterns PXP in the display area DPA that have the same potential as the second power supply lines ELVSL, third-type pixels PXT3, in which the common electrode CME is in contact with sub-electrode patterns PXET in the non-display area NDA that have the same potential as the second power supply lines ELVSL, and second-type pixels PXT2, in which the common electrode CME is not in contact with patterns having the same potential as the second power supply lines ELVSL. Because the display device 1 includes the first-type pixels PXT1 and further includes the third-type pixels PXT3, a drop in the second power supply voltage ELVS, which is applied to the common electrode CME, can be suppressed, and the number of laser irradiation processes can be reduced or minimized by reducing the number of first-type pixels PXT1 where opening holes HLD are formed.

Referring again to FIG. 11, the third-type pixels PXT3 may be disposed in the outermost part of the display area DPA, near the non-display area NDA, and the first-type pixels PXT1 may be arranged on the inside (e.g., the inner area) of the display area DPA from the pixel rows PXC or the pixel columns PXC where the third-type pixels PXT3 are arranged. For example, in the first pixel column PXL1, only the second-type pixels PXT2 and the third-type pixels PXT3 may be arranged, in the second and third pixel columns PXL2 and PXL3, only the second-type pixels PXT2 may be arranged, and in the fourth pixel column PXL4, only the first-type pixels PXT1 and the second-type pixels PXT2 may be arranged. As the first-type pixels PXT1 are arranged only in the fourth pixel column PXL4 and pixel columns PXL subsequent to the fourth pixel column PXL4, a first-type pixel area PXTL where only the first-type pixels PXT1 are arranged may be defined.

The first-type pixel area PTXL may be an area where the openings holes HLD of the first-type pixels PXT1 are arranged and where the application of laser light is performed during the fabrication of the display device 1. The size of the first-type pixel area PTXL may vary depending on how the third-type pixels PXT3 are arranged in the outermost part of the display area DPA. FIG. 11 illustrates that the third-type pixels PXT3 are arranged only one side of the display area DPA, and that pixel columns PXL subsequent to the fourth pixel column PXL4 form the first-type pixel area PXTL. In one embodiment, the size of the first-type pixel area PXTL may be smaller than the size of the display area DPA, but the disclosure is not limited thereto. In other embodiments, the third-type pixels PXT3 may be disposed on more than one side of the display area DPA, in which case, the size of the first-type pixel area PXTL may be reduced accordingly. This will be described later.

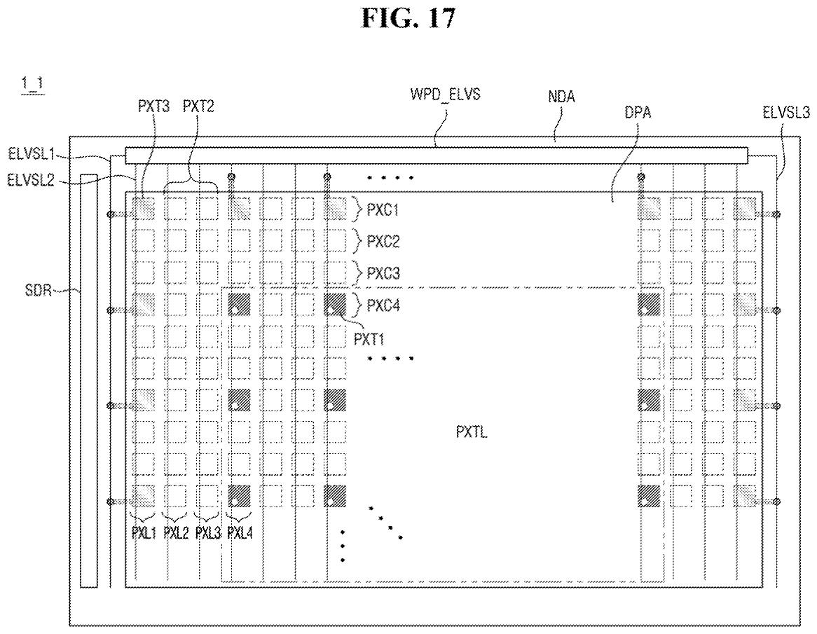

FIGS. 17 through 20 are schematic views illustrating the layout of pixels in display devices according to other embodiments of the disclosure.

FIGS. 17 through 20 illustrate different layouts of a plurality of pixels PX for explaining how the layout of first-type pixels PXT1 may change (or vary) depending on the layout of third-type pixels PXT3. Descriptions of features or elements that have already been described above may be omitted or simplified, and the embodiments of FIGS. 17 through 20 will hereinafter be described, focusing primarily on the differences with the previous embodiment.

Referring to a display device 1_1 shown in FIG. 17, third-type pixels PXT3 may be arranged in more than one outermost part of a display area DPA. For example, the third-type pixels PXT3 may be further arranged in a first pixel column PXL1, which is adjacent to a third non-display area (see, e.g., NDA3 of FIG. 1) where a 21^{st} power supply line ELVSL1 is disposed. The third-type pixels PXT3 may also be arranged on a side of the display area DPA adjacent to a fourth non-display area where a 23^{rd} power supply line ELVSL3 is disposed. The embodiment differs from the embodiment shown in FIG. 11 in that a relatively great number of third-type pixels PXT3 are provided.

In the third-type pixels PXT3 arranged in the first pixel column PXL1, on one side of the display area DPA, the common electrode CME may be in contact with sub-electrode patterns PXET having the same potential as the 21^{st} power supply line ELVSL1, as already mentioned above with reference to FIG. 11.

Third-type pixels PXT3 may also be disposed on the other side of the display area DPA. In the third-type pixels PXT3 disposed on the other side of the display area DPA, the common electrode CME may be electrically connected to the 23^{rd} power supply line ELVSL3. Sub-electrode patterns PXET overlapping with the 23^{rd} power supply line ELVSL3 in the thickness direction may be disposed in the fourth non-display area and may have the same potential as the 23^{rd} power supply line ELVSL3 by being in contact with parts of the 23^{rd} power supply line ELVSL3, exposed by power supply contact holes CNTN. Because the common electrode CME is in contact with the sub-electrode patterns PXET, in third-type pixels PXT3 arranged near the 23^{rd} power supply line ELVSL3, the common electrode CME may be electrically connected to the 23^{rd} power supply line ELVSL3. Accordingly, in the display device 1_1, at least one first-type pixel PXT1 may be arranged between two arbitrary third-type pixels PXT3.

The third-type pixels PXT3 may also be arranged in the first pixel row PXC1, and third-type pixels PXT3 arranged in the first pixel row PXC1 may be electrically connected to a 22^{nd} power supply line ELVSL2, which is disposed in a second non-display area (see, e.g., NDA2 of FIG. 1). In this embodiment, unlike in the embodiment shown in FIG. 11, the third-type pixels PXT3, rather than the first-type pixels PXT1, may be arranged in the first pixel row PXC1 so that opening holes HLD may not be formed in the first pixel row PXC1.

Accordingly, in the display device 1_1 shown in FIG. 17, a first-type pixel area PXTL_1, where opening holes HLD are formed, may be positioned in a fourth pixel column PXL4 and pixel columns subsequent to a fourth pixel row PXC4 and in the fourth pixel row PXC4 and pixel rows subsequent to the fourth pixel row PXC4. Opening holes HLD may not be formed in pixel columns PXL on the other side of the display area DPA. As a relatively great number of third-type pixels PXT3 are provided in the display device 1_1, the first-type pixel area PXTL_1 may have a smaller size than its counterpart shown in FIG. 11. Laser irradiation processes for forming opening holes HLD may be performed only in part of the display area DPA.

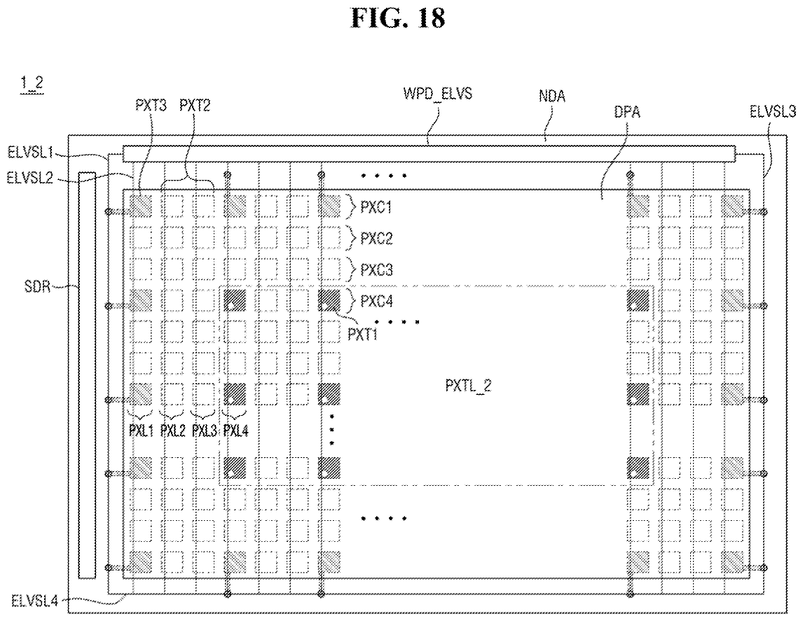

Referring to a display device 1_2 shown in FIG. 18, second power supply lines ELVSL may further include a 24^{th} power supply line ELVSL4, which is connected to both 21^{st} and 23^{rd} power supply lines ELVSL1 and ELVSL3 and extends in a direction perpendicular to the direction in which the 21^{st} and 23^{rd} power supply lines ELVSL1 and ELVSL3 extend. The second power supply lines ELVSL may include a second power supply pad WPD_ELVS to surround (e.g., to extend around the periphery of) the display area DPA. Accordingly, the display device 1_2 may further include third-type pixels PXT3, which are arranged in a pixel row PXC adjacent to the 24^{th} power supply line ELVSL4. In the third-type pixels PXT3, a common electrode CME may be electrically connected to the 24^{th} power supply line ELVSL4, and a first-type pixel area PXTL_2 may have a relatively small size. This embodiment is the same as the embodiment shown in FIG. 17 except that the first-type pixel area PXTL_2 is formed to be spaced apart from an outer part of the display area DPA, and thus, a detailed description thereof will be omitted.

Pixels other than first-type pixels PXT1 and the third-type pixels PXT3, in which the common electrode CME is electrically connected to the second power supply lines ELVSL, may be second-type pixels PXT2 where opening holes HLD are not formed. In this and previous embodiments, two second-type pixels PXT2 may be disposed between each pair of adjacent first- and third-type pixels PXT1 and PXT3, between each pair of adjacent first-type pixels PXT1, and between each pair of adjacent third-type pixels PXT3, but the disclosure is not limited thereto.

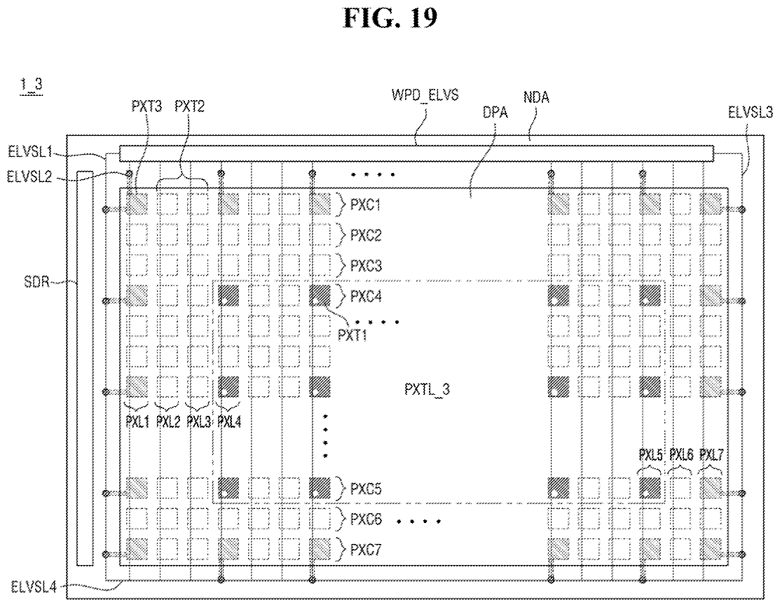

Referring to a display device 1_3 shown in FIG. 19, there may exist pixel columns PXL and pixel rows PXC where the number of second-type pixels PXT2 disposed between each pair of adjacent first-type pixels PXT1, between each pair of adjacent third-type pixels PXT3, or between each pair of adjacent first- and third-type pixels PXT1 and PXT3 differs from other pixel columns PXL and other pixel rows PXC. This embodiment is the same as the embodiment shown in FIG. 18 except for the distances between first-type pixels PXT1, between third-type pixels PXT3, and between the first-type pixels PXT1 and the third-type pixels PXT3 and, thus, it will hereinafter be described, focusing primarily on the differences with the embodiment shown in FIG. 18.

The third-type pixels PXT3 may be arranged in a first pixel column PXL1 and in a first pixel row PXC1, and the first-type pixels PXT1 may be disposed to be spaced a distance (e.g., a predetermined distance) apart from the third-type pixels PXT3. The first-type pixels PXT1 may be arranged in pixel columns PXL ranging from a fourth pixel column PXL4 and in pixel rows PXC ranging from a fourth pixel row PXC4, within an area (e.g., a predetermined area), to form a first-type pixel area PXTL_3. In this embodiment, second-type pixels PXT2 are arranged in an area between the first and fourth pixel columns PXL1 and PXL4 and between the first and fourth pixel rows PXC1 and PXC4, excluding places where the first-type pixels PXT1 and the third-type pixels PXT3 are disposed, and two second-type pixels PXT2 may be arranged between each pair of adjacent first-type pixels PXT1, between each pair of adjacent third-type pixels PXT3, and between each pair of adjacent first- and third-type pixels PXT1 and PXT3. For example, the first-type pixels PXT1 and/or the third-type pixels PXT3 may be arranged at regular intervals in the area between the first and fourth pixel columns PXL1 and PXL4 and between the first and fourth pixel rows PXC1 and PXC4.

The first-type pixel area PXTL_3 may be positioned over an area (e.g., a predetermined area) ranging from the fourth pixel column PXL4 and the fourth pixel row PXC4. When the first-type pixels PXT1 are arranged in the last pixel column PXL and the last pixel row PXC of the first-type pixel area PXTL_3, i.e., in a fifth pixel column PXLS and a fifth pixel row PXCS in FIG. 19, and the third-type pixels PXT3 are arranged in the last pixel column PXL and the last pixel row PXC of the display area DPA, i.e., in a seventh pixel column PXL7 and a seventh pixel row PXC7 in FIG. 19, only one second-type pixel PXT2 may be arranged between each pair of adjacent first- and third-type pixels PXT1 and PXT3.

For example, only one second-type pixel PXT2 may be arranged between a first-type pixel PXT1 in the fifth pixel column PXLS and its neighboring third-type pixel PXT3 in the seventh pixel column PXL7 and between the first-type pixel PXT1 in the fifth pixel column PXLS and its neighboring third-type pixel PXT3 in the seventh pixel row PXC7. Also, only one second-type pixel PXT2 may be arranged between a third-type pixel PXT1 in the fifth pixel row PXCS and its neighboring third-type pixel PXT3 in the seventh pixel row PXC7. The display device 1_3 may include areas (or pixel columns PXL and pixel rows PXC) where the distances between the first-type pixels PXT1, between the third-type pixels PXT3, and between the first-type pixels PXT1 and the third-type pixels PXT3 vary. When the first-type pixel area PXTL_3, having opening holes HLD formed therein, is formed by applying laser light to a predetermined area from the fourth pixel column PXL4 and the fourth pixel row PXC4 of the display area DPA, the first-type pixels PXT1 and the third-type pixels PXT3 may be arranged in the predetermined area to have a different distance therebetween from the rest of the display area DPA.

The distance between the first-type pixels PXT1 and the third-type pixels PXT3 may vary depending on the period of laser irradiation processes for forming the first-type pixel area PXTL_3. FIG. 19 illustrates that the distance between the first-type pixels PXT1 in the first-type pixel area PXTL_3 is greater than the distance between the fifth and seventh pixel columns PXLS and PXL7 and the distance between the fifth pixel row PXCS and the seventh pixel row PXC7, but the disclosure is not limited thereto. In other embodiments, the distance between the first-type pixels PXT1 in the first-type pixel area PXTL_3 may be smaller than the distance between the fifth and seventh pixel columns PXLS and PXL7 and the distance between the fifth and seventh pixel rows PXCS and PXC7.

For example, in the display device 1_3, the distance between pixel columns PXL may differ from the left side to the right side of the center of the display area DPA, and the distance between pixel rows PXC may differ from the upper side to the lower side of the center of the display area DPA. As illustrated in FIG. 19, the first-type pixel area PXTL_3 may be disposed closer to the right side than to the left side of the display area DPA and closer to the upper side than to the lower side of the display area DPA, but the disclosure is not limited thereto.

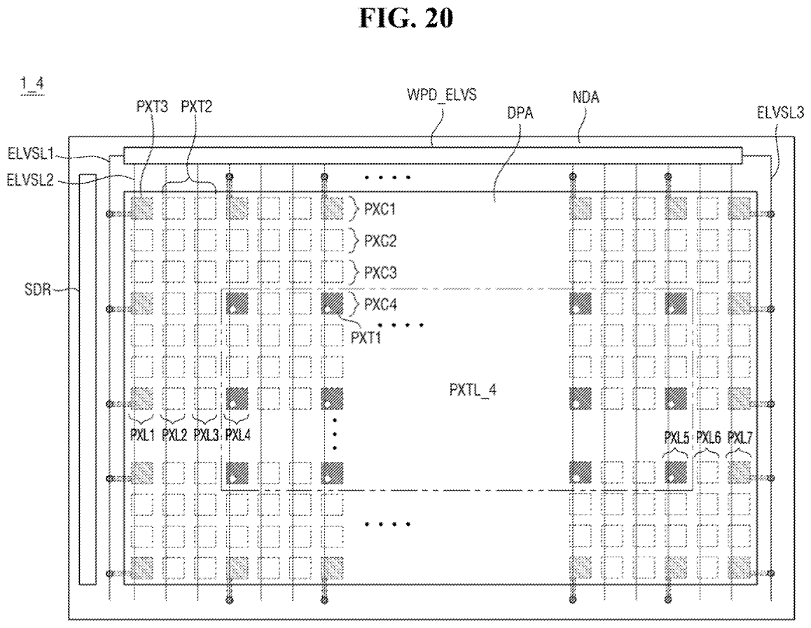

Referring to a display device 1_4 shown in FIG. 20, the distance between pixel rows PXC may be uniform from the upper side to the lower side of the center of a display area DPA, but the distance between pixel columns PXL may differ from the left side to the right side of the center of the display area DPA. As illustrated in FIG. 20, a first-type pixel area PXTL_4 may be disposed closer to the right side than to the left side of the display area DPA and may be spaced apart from both the upper and lower sides of the display area DPA by the same distance. The display device 1_4, different from the display device 1_3 shown in FIG. 19, does not include a 24th power supply line ELVSL4 so that the distance between a plurality of pixel rows PXC is uniform. Instead, the display device 1_4 includes 21^{st} and 23^{rd} power supply lines ELVSL1 and ELVSL3 so that the distance between a plurality of pixel columns PXL varies. In the display device 1_4 shown in FIG. 20, the distance between first and fourth pixel columns PXL1 and PXL4 may differ from the distance between fifth and seventh pixel columns PXLS and PXL7. Other features of the display device 1_4 are almost the same as already mentioned above, and thus, detailed descriptions thereof will be omitted.

In concluding the detailed description, those skilled in the art will appreciate that many variations and modifications can be made to the embodiments described herein without substantially departing from the aspects and features of the disclosure. Therefore, the disclosed embodiments of the disclosure are used in a generic and descriptive sense and not for purposes of limitation.

1.-20. (canceled)

21. A display device having a display area and a non-display area extending around the display area, the display device comprising:
a plurality of pixels in the display area;
a first voltage line in the display area; and
a second voltage line in the non-display area,
wherein:
each of the pixels comprises an electrode pattern connected to the first voltage line, a pixel-defining film on the electrode pattern, an emission layer on the pixel-defining film, and a common electrode on the emission layer,
the pixels comprise first-type pixels in which the common electrode and the electrode pattern are connected through an opening hole formed in the pixel-defining film and exposing part of the electrode pattern and second-type pixels in which the opening hole is not formed and the common electrode and the electrode pattern are not connected, and
the first-type pixels and the second-type pixels are adjacent to each other.

22. The display device of claim 21, further comprising a sub-electrode pattern in the non-display area and connected to the second voltage line,
wherein the pixels further comprise third-type pixels in which the common electrode is connected to the sub-electrode pattern.

23. The display device of claim 22, wherein the third-type pixels are spaced apart from the first-type pixels, and
wherein at least one of the second-type pixels is between the first-type pixels and the third-type pixels.

24. The display device of claim 23, wherein a plurality of the first-type pixels are spaced apart from one another, and
wherein the second-type pixels are between the plurality of spaced apart first-type pixels.

25. The display device of claim 23, wherein a plurality of the third-type pixels are spaced apart from one another, and
wherein the third-type pixels are between the plurality of spaced apart third-type pixels.

26. The display device of claim 22, wherein the third-type pixels are on at least one side of the display area, and
wherein the first-type pixels are on the inside of the display area and spaced apart from the third-type pixels.

27. The display device of claim 26, wherein at least one of the first-type pixels is between the third-type pixels.

28. The display device of claim 22, wherein the display area has a plurality of pixel columns in which the pixels are arranged along a first direction, and
wherein the pixel columns have a first pixel column comprising at least one of the first-type pixels and a second pixel column comprising the second-type pixels.

29. The display device of claim 28, wherein the first-type pixels and the third-type pixels are not in the second pixel column.

30. The display device of claim 28, wherein the pixel columns also have a third pixel column comprising at least one of the first-type pixels and at least one of the third-type pixels.

31. The display device of claim 30, wherein the third pixel column further comprises at least one of the second-type pixels between the at least one of the first-type pixels and the at least one of the third-type pixels.

32. The display device of claim 31, wherein the pixel columns also have a fourth pixel column comprising at least one of the second-type pixels between the first-type pixels, between the third-type pixels, or between the first-type pixels and the third-type pixels, and
wherein a number of second-type pixels between the first-type pixels and the third-type pixels in the third pixel column differs from a number of the second-type pixels between the first-type pixels and the third-type pixels in the fourth pixel column.

33. The display device of claim 28, wherein the display area has a plurality of pixel rows in which the pixels are arranged in a second direction intersecting the first direction, and
wherein the pixel rows have a first pixel row comprising at least one of the first-type pixels and a second pixel row comprising at least one of the second-type pixels.

34. The display device of claim 33, wherein the first pixel row further comprises at least one of the third-type pixels and at least one of the second-type pixels between the at least one of the third-type pixels and the at least one of the first-type pixels.

35. The display device of claim 22, wherein a first-type pixel area where the first-type pixels are arranged is defined in the display area, and
wherein at least one side of the first-type pixel area is spaced apart from the non-display area.

36. The display device of claim 35, wherein a size of the first-type pixel area is smaller than a size of the display area.

37. The display device of claim 21, wherein each of the pixels further comprises at least one pixel electrode in the same layer as, but spaced apart from, the electrode pattern, and
wherein the emission layer is between the pixel-defining film and the common electrode.

38. The display device of claim 37, wherein the pixel-defining film has an opening exposing part of the pixel electrode, and
wherein in the opening, the emission layer is between the common electrode and the pixel electrode, but not on part of the electrode pattern exposed by the opening hole.

39. A display device having a display area and a non-display area, the display device comprising:
a data conductive layer comprising a first voltage line in the display area and a second voltage line in the non-display area;
a passivation film on the data conductive layer and covering the first and second voltage lines;
a planarization film on the passivation film;
a pixel electrode layer on the planarization film and comprising:
an electrode pattern in the display area and connected to the first voltage line; and
a sub-electrode pattern in the non-display area and connected to the second voltage line;
a pixel-defining film on the planarization film and the electrode pattern;
an emission layer on the pixel-defining film; and
a common electrode on the emission layer and connected to the sub-electrode pattern,
wherein the electrode pattern comprises a first electrode pattern not connected to the common electrode and a second electrode pattern connected to the common electrode.

40. The display device of claim 39, wherein the pixel-defining film has an opening hole exposing part of the second electrode pattern, and
wherein the second electrode pattern is connected to the common electrode through the opening hole.
